(19) United States
(12) Patent Application Publication
(10) Pub. No.: US 2024/0288550 A1
(43) Pub. Date: Aug. 29, 2024

(54) METHOD, SYSTEM AND COMPUTER READABLE MEDIUM FOR EVALUATING INFLUENCE OF AN ACTION PERFORMED BY AN EXTERNAL ENTITY

(71) Applicant: LeddarTech Inc., Quebec (CA)

(72) Inventors: Ricardo Ferreira, Ottobrunn (DE); Stefan Hadrath, Falkensee (DE); Peter Hoehmann, Berlin (DE); Herbert Kaestle, Traunstein (DE); Florian Kolb, Jena (DE); Norbert Magg, Berlin (DE); Jiye Park, Munich (DE); Tobias Schmidt, Garching (DE); Martin Schnarrenberger, Berlin (DE); Norbert Haas, Langenau (DE); Helmut Horn, Achberg (DE); Bernhard Siessegger, Unterschleissheim (DE); Guido Angenendt, Munich (DE); Charles Braquet, Munich (DE); Gerhard Maierbacher, Munich (DE); Oliver Neitzke, Berlin (DE); Sergey Khrushchev, Regensburg (DE)

(21) Appl. No.: 18/649,344

(22) Filed: Apr. 29, 2024

Related U.S. Application Data
(63) Continuation of application No. 18/514,827, filed on Nov. 20, 2023.
Application No. 18/514,827 is a continuation of application No. 18/318,538, filed on May 16, 2023, now abandoned.
Application No. 18/318,538 is a continuation of application No. 16/809,587, filed on Mar. 5, 2020, now Pat. No. 11,726,184.

(30) Foreign Application Priority Data
Mar. 8, 2019 (DE) 102019203175.7
Apr. 16, 2019 (DE) 102019205514.1
May 14, 2019 (DE) 102019206939.8
Jun. 12, 2019 (DE) 102019208489.3
Jul. 17, 2019 (DE) 102019210528.9
Sep. 2, 2019 (DE) 102019213210.3
Sep. 23, 2019 (DE) 102019214455.1
Oct. 24, 2019 (DE) 102019216362.9
Nov. 6, 2019 (DE) 102019217097.8
Nov. 22, 2019 (DE) 102019218025.6
Dec. 17, 2019 (DE) 102019219775.2
Jan. 24, 2020 (DE) 102020200833.7
Feb. 10, 2020 (DE) 102020201577.5
Feb. 17, 2020 (DE) 102020201900.2
Feb. 25, 2020 (DE) 102020202374.3

(51) Int. Cl. G01S 7/481; G01S 7/484; G01S 17/931

(52) U.S. Cl. CPC G01S 7/4817; G01S 7/4811; G01S 7/4815; G01S 7/4816; G01S 7/484; G01S 17/931

(57) ABSTRACT

The present disclosure provides a non-transitory computer readable medium having instructions tangibly stored thereon, wherein when executed by a processing entity, the instructions cause the processing entity to carry out a method of evaluating influence of an action performed by an external entity, the method comprising: receiving sensor data; determining a signal reliability factor for the received sensor data, wherein the signal reliability factor represents a statistical quality indication between the received sensor data and an expected value or an expected range of values; and associating the signal reliability factor with the received sensor data. There is also provided a system configured to communicate with an autonomous driving system.

### CROSS-REFERENCE TO RELATED APPLICATIONS

The present application is a continuation of U.S. patent application Ser. No. 18/514,827, filed Nov. 20, 2023, which is a continuation of U.S. patent application Ser. No. 18/318,538, filed May 16, 2023, which is a continuation of U.S. patent application Ser. No. 16/809,587, filed on Mar. 5, 2020, now U.S. Pat. No. 11,726,184, which claims priority from and the benefit of: (i) German Application No.: 10 2019 205 514.1, filed on Apr. 16, 2019, (ii) German Application No.: 10 2019 214 455.1, filed on Sep. 23, 2019, (iii) German Application No.: 10 2019 216 362.9, filed on Oct. 24, 2019, (iv) German Application No.: 10 2020 201 577.5, filed on Feb. 10, 2020, (v) German Application No.: 10 2019 217 097.8, filed on Nov. 6, 2019, (vi) German Application No.: 10 2020 202 374.3, filed on Feb. 25, 2020, (vii) German Application No.: 10 2020 201 900.2, filed on Feb. 17, 2020, (viii) German Application No.: 10 2019 203 175.7, filed on Mar. 8, 2019, (ix) German Application No.: 10 2019 218 025.6, filed on Nov. 22, 2019, (x) German Application No.: 10 2019 219 775.2, filed on Dec. 17, 2019, (xi) German Application No.: 10 2020 200 833.7, filed on Jan. 24, 2020, (xii) German Application No.: 10 2019 208 489.3, filed on Jun. 12, 2019, (xiii) German Application No.: 10 2019 210 528.9, filed on Jul. 17, 2019, (xiv) German Application No.: 10 2019 206 939.8, filed on is May 14, 2019, and (xv) German Application No.: 10 2019 213 210.3, filed on Sep. 2, 2019. The contents of each of the aforementioned U.S. and German applications are incorporated herein by reference in their entirety.

### TECHNICAL FIELD

The technical field of the present disclosure relates generally to sensor systems and, more specifically, to a method, system and computer readable medium for evaluating influence of an action performed by an external entity.

### BACKGROUND

There are numerous studies and market forecasts, which predict that future mobility and transportation will shift from vehicles supervised by a human operator to vehicles with an increasing level of autonomy towards fully autonomous, self-driving vehicles. This shift, however, will not be an abrupt change but rather a gradual transition with different levels of autonomy, defined for example by SAE International (Society of Automotive Engineers) in SAE J3016 in-between. Furthermore, this transition will not take place in a simple linear manner, advancing from one level to the next level, while rendering all previous levels dispensable. Instead, it is expected that these levels of different extent of autonomy will co-exist over longer periods of time and that many vehicles and their respective sensor systems will be able to support more than one of these levels.

Depending on various factors, a human operator may actively switch for example between different SAE levels, depending on the vehicle's capabilities, or the vehicles operation system may request or initiate such a switch, typically with a timely information and acceptance period to possible human operators of the vehicles. These factors may include internal factors such as individual preference, level of driving experience or the biological state of a human driver and external factors such as a change of environmental conditions like weather, traffic density or unexpected traffic complexities.

It is important to note that the above-described scenario for a future is not a theoretical, far-away eventuality. In fact, already today, a large variety of so-called Advanced Driver Assistance Systems (ADAS) has been implemented in modern vehicles, which clearly exhibit characteristics of autonomous vehicle control. Current ADAS systems may be configured for example to alert a human operator in dangerous situations (e.g. lane departure warning) but in specific driving situations, some ADAS systems are able to takeover control and perform vehicle steering operations without active selection or intervention by a human operator. Examples may include convenience-driven situations such as adaptive cruise control, but also hazardous situations like in the case of lane keep assistants and emergency break assistants.

The above-described scenarios all require vehicles and transportation systems with a tremendously increased capacity to perceive, interpret and react on their surroundings. Therefore, it is not surprising that remote environmental sensing systems will be at the heart of future mobility.

Since modern traffic can be extremely complex due to a large number of heterogeneous traffic participants, changing environments or insufficiently mapped or even unmapped environments, and due to rapid, interrelated dynamics, such sensing systems will have to be able to cover a broad range of different tasks, which have to be performed with a high level of accuracy and reliability. It turns out that there is not a single “one fits all” sensing system that can meet all the required features relevant for semi-autonomous or fully autonomous vehicles. Instead, future mobility requires different sensing technologies and concepts with different advantages and disadvantages. Differences between sensing systems may be related to perception range, vertical and horizontal field of view (FOV), spatial and temporal resolution, speed of data acquisition, etc. Therefore, sensor fusion and data interpretation, possibly assisted by Deep Neuronal Learning (DNL) methods and other Neural Processor Units (NFU) methods for more complex tasks, like judgment of a traffic situation and generation of derived vehicle control functions, may be necessary to cope with such complexities. Furthermore, driving and steering of autonomous vehicles may require a set of ethical rules and commonly accepted traffic regulations.

Among these sensing systems, LIDAR sensing systems are expected to play a vital role, as well as camera-based systems, possibly supported by radar and ultrasonic systems. With respect to a specific perception task, these systems may operate more or less independently of each other. However, in order to increase the level of perception (e.g. in terms of accuracy and range), signals and data acquired by different sensing systems may be brought together in so-called sensor fusion systems. Merging of sensor data is not only necessary to refine and consolidate the measured results but also to increase the confidence in sensor results by resolving possible inconsistencies and contradictories and by providing a certain level of redundancy. Unintended spurious signals and intentional adversarial attacks may play a role in this context as well.

For an accurate and reliable perception of a vehicle's surrounding, not only vehicle-internal sensing systems and measurement data may be considered but also data and information from vehicle-external sources. Such vehicle-external sources may include sensing systems connected to other traffic participants, such as preceding and oncoming vehicles, pedestrians, and cyclists, but also sensing systems mounted on road infrastructure elements like traffic lights, traffic signals, bridges, elements of road construction sites and central traffic surveillance structures. Furthermore, data and information may come from far-away sources such as traffic teleoperators and satellites of global positioning systems (e.g. GPS).

Therefore, apart from sensing and perception capabilities, future mobility will also heavily rely on capabilities to communicate with a wide range of communication partners. Communication may be unilateral or bilateral and may include various wireless transmission technologies, such as WLAN, Bluetooth and communication based on radio frequencies and visual or non-visual light signals. It is to be noted that some sensing systems, for example LIDAR sensing systems, may be utilized for both sensing and communication tasks, which makes them particularly interesting for future mobility concepts. Data safety and security and unambiguous identification of communication partners are examples where light-based technologies have intrinsic advantages over other wireless communication technologies. Communication may need to be encrypted and tamper-proof.

From the above description, it becomes clear also that future mobility has to be able to handle vast amounts of data, as several tens of gigabytes may be generated per driving hour. This means that autonomous driving systems have to acquire, collect and store data at very high speed, usually complying with real-time conditions. Furthermore, future vehicles have to be able to interpret these data, i.e. to derive some kind of contextual meaning within a short period of time in order to plan and execute required driving maneuvers. This demands complex software solutions, making use of is advanced algorithms. It is expected that autonomous driving systems will including more and more elements of artificial intelligence, machine and self-learning, as well as Deep Neural Networks (DNN) for certain tasks, e.g. visual image recognition, and other Neural Processor Units (NFU) methods for more complex tasks, like judgment of a traffic situation and generation of derived vehicle control functions, and the like. Data calculation, handling, storing and retrieving may require a large amount of processing power and hence electrical power.

In an attempt to summarize and conclude the above paragraphs, future mobility will involve sensing systems, communication units, data storage devices, data computing and signal processing electronics as well as advanced algorithms and software solutions that may include and offer various ethical settings. The combination of all these elements is constituting a cyber-physical world, usually denoted as the Internet of things (IoT). In that respect, future vehicles represent some kind of IoT device as well and may be called “Mobile IoT devices”.

Such “Mobile IoT devices” may be suited to transport people and cargo and to gain or provide information. It may be noted that future vehicles are sometimes also called “smartphones on wheels”, a term which surely reflects some of the capabilities of future vehicles. However, the term implies a certain focus towards consumer-related new features and gimmicks. Although these aspects may certainly play a role, it does not necessarily reflect the huge range of future business models, in particular data-driven business models, that can be envisioned only at the present moment of time, but which are likely to center not only on personal, convenience driven features but include also commercial, industrial or legal aspects.

New data-driven business models will focus on smart, location-based services, utilizing for example self-learning and prediction aspects, as well as gesture and language processing with Artificial Intelligence as one of the key drivers. All this is fueled by data, which will be generated in vast amounts in automotive industry by a large fleet of future vehicles acting as mobile digital platforms and by connectivity networks linking together mobile and stationary IoT devices.

New mobility services including station-based and free-floating car sharing, as well as ride-sharing propositions have already started to disrupt traditional business fields. This trend will continue, finally providing robo-taxi services and sophisticated Transportation-as-a-Service (TaaS) and Mobility-as-a-Service (MaaS) solutions.

Electrification, another game-changing trend with respect to future mobility, has to be considered as well. Hence, future sensing systems will have to pay close attention to system efficiency, weight and energy-consumption aspects. In addition to an overall minimization of energy consumption, also context-specific optimization strategies, depending for example on situation-specific or location-specific factors, may play an important role.

Energy consumption may impose a limiting factor for autonomously driving electrical vehicles. There are quite a number of energy consuming devices like sensors, for example RADAR, LIDAR, camera, ultrasound, Global Navigation Satellite System (GNSS/GPS), sensor fusion equipment, processing power, mobile entertainment equipment, heater, fans, Heating, Ventilation and Air Conditioning (HVAC), Car-to-Car (C2C) and Car-to-Environment (C2X) communication, data encryption and decryption, and many more, all leading up to a high power consumption. Especially data processing units are very power hungry. Therefore, it is necessary to optimize all equipment and use such devices in intelligent ways so that a higher battery mileage can be sustained.

Besides new services and data-driven business opportunities, future mobility is expected also to provide a significant reduction in traffic-related accidents. Based on data from the Federal Statistical Office of is Germany (Destatis, 2018), over 98% of traffic accidents are caused, at least in part by humans. Statistics from other countries display similarly clear correlations.

Nevertheless, it has to be kept in mind that automated vehicles will also introduce new types of risks, which have not existed before. This applies to so far unseen traffic scenarios, involving only a single automated driving system as well as for complex scenarios resulting from dynamic interactions between a plurality of automated driving system. As a consequence, realistic scenarios aim at an overall positive risk balance for automated driving as compared to human driving performance with a reduced number of accidents, while tolerating to a certain extent some slightly negative impacts in cases of rare and unforeseeable driving situations. This may be regulated by ethical standards that are possibly implemented in soft- and hardware.

Any risk assessment for automated driving has to deal with both, safety and security related aspects: safety in this context is focusing on passive adversaries for example due to malfunctioning systems or system components, while security is focusing on active adversaries for example due to intentional attacks by third parties.

In the following a non-exhaustive enumeration is given for safety-related and security-related factors, with reference to “Safety first for Automated Driving”, a white paper published in 2019 by authors from various Automotive OEM, Tier-1 and Tier-2 suppliers.

Safety assessment: to meet the targeted safety goals, methods of verification and validation have to be implemented and executed for all relevant systems and components. Safety assessment may include safety by design principles, quality audits of the development and production processes, the use of redundant sensing and analysis components and many other concepts and methods.

Safe operation: any sensor system or otherwise safety-related system might be prone to degradation, i.e. system performance may decrease over time or a system may even fail completely (e.g. being unavailable). To ensure safe operation, the system has to be able to compensate for such performance losses for example via redundant sensor systems. In any case, the system has to be configured to transfer the vehicle into a safe condition with acceptable risk. One possibility may include a safe transition of the vehicle control to a human vehicle operator.

Operational design domain: every safety-relevant system has an operational domain (e.g. with respect to environmental conditions such as temperature or weather conditions including rain, snow and fog) inside which a proper operation of the system has been specified and validated. As soon as the system gets outside of this domain, the system has to be able to compensate for such a situation or has to execute a safe transition of the vehicle control to a human vehicle operator.

Safe layer: the automated driving system needs to recognize system limits in order to ensure that it operates only within these specified and verified limits. This includes also recognizing limitations with respect to a safe transition of control to the vehicle operator.

User responsibility: it must be clear at all times which driving tasks remain under the user's responsibility. In addition, the system has to be able to determine factors, which represent the biological state of the user (e.g. state of alertness) and keep the user informed about their responsibility with respect to the user's remaining driving tasks.

Human Operator-initiated handover: there have to be clear rules and explicit instructions in case that a human operator requests an engaging or disengaging of the automated driving system.

Vehicle-initiated handover: requests for such handover operations have to be clear and manageable by the human operator, including a sufficiently long time period for the operator to adapt to the current traffic situation. In case it turns out that the human operator is not available or not capable of a safe takeover, the automated driving system must be able to perform a minimal-risk maneuver.

Behavior in traffic: automated driving systems have to act and react in an easy-to-understand way so that their behavior is predictable for other road users. This may include that automated driving systems have to observe and follow traffic rules and that automated driving systems inform other road users about their intended behavior, for example via dedicated indicator signals (optical, acoustic).

Security: the automated driving system has to be protected against security threats (e.g. cyber-attacks), including for example unauthorized access to the system by third party attackers. Furthermore, the system has to be able to secure data integrity and to detect data corruption, as well as data forging. Identification of trustworthy data sources and communication partners is another important aspect. Therefore, security aspects are, in general, strongly linked to cryptographic concepts and methods.

Data recording: relevant data related to the status of the automated driving system have to be recorded, at least in well-defined cases. In addition, traceability of data has to be ensured, making strategies for data management a necessity, including concepts of bookkeeping and tagging. Tagging may comprise, for example, to correlate data with location information, e.g. GPS-information.

In the following disclosure, various aspects are disclosed which may be related to the technologies, concepts and scenarios presented in the section “BACKGROUND”. This disclosure is focusing on LIDAR Sensor Systems, Controlled LIDAR Sensor Systems and LIDAR Sensor Devices as well as Methods for LIDAR Sensor Management. As illustrated in the above remarks, automated driving systems are extremely complex systems including a huge variety of interrelated sensing systems, communication units, data storage devices, data computing and signal processing electronics as well as advanced algorithms and software solutions.

### SUMMARY

A first aspect of the present disclosure provides a non-transitory computer readable medium, which has instructions tangibly stored thereon, wherein when executed by a processing entity, the instructions cause the processing entity to carry out a method of evaluating influence of an action performed by an external entity, the method comprising: receiving sensor data; determining a signal reliability factor for the received sensor data, wherein the signal reliability factor represents a statistical quality indication between the received sensor data and an expected value or an expected range of values; and associating the signal reliability factor with the received sensor data.

In accordance with the preceding aspect, the method may further comprise determining if the signal reliability factor satisfies criteria; and discarding the received sensor data or using the received sensor data to generate one or more commands which are configured to control a central control system, depending on whether the signal reliability factor satisfies the criteria.

In accordance with the preceding aspect, the criteria may be satisfied if the signal reliability factor is less than a predefined threshold or the signal reliability factor is between a lower threshold and an upper threshold.

In accordance with the preceding aspect, the expected value or the expected range of values may be based on immediately preceding sensor data, the immediately preceding sensor data being received at an antecedent time point with respect to a time point when the sensor data is received.

In accordance with the preceding aspect, a sensor system that generates the immediately preceding sensor data may be identical to a sensor system that generates the received sensor data.

In accordance with the preceding aspect, in response to the signal reliability factor indicating that the received sensor data is incoherent with the immediately preceding sensor data, the method may further comprise evaluating influence of the action performed by the external entity based on the signal reliability factor.

In accordance with the preceding aspect, the received sensor data may be first sensor data generated by a first sensor system, and the method may further comprise receiving second sensor data from a second sensor system; and statistically inferring the expected value or the expected range of values based on the second sensor data.

In accordance with the preceding aspect, the processing entity may be associated with a vehicle, and the method may further comprise determining a vehicle condition associated with the vehicle; and statistically inferring the expected value or the expected range of values based on the vehicle condition.

In accordance with the preceding aspect, the vehicle condition may include at least one of a location selective category, an environmental setting, and a driving status.

In accordance with the preceding aspect, the method may further comprise determining a sensor fusion priority corresponding to the vehicle condition, wherein the sensor fusion priority defines a particular number and combination of sensor systems to be used.

In accordance with the preceding aspect, the sensor data may be generated by one or more sensor systems, and the method may further comprise changing a configuration of the one or more sensor systems based on the signal reliability factor.

In accordance with the preceding aspect, changing the configuration of the one or more sensor systems may comprise deactivating and/or deprioritizing at least one of the one or more sensor systems.

In accordance with the preceding aspect, the signal reliability factor may indicate a probability of the received sensor data being influenced by the action performed by the external entity.

In accordance with the preceding aspect, determining the signal reliability factor may comprise applying statistical rules to the received sensor data and the expected value or the expected range to generate the statistical quality indication, wherein the statistical rules include Bayesian rulings or position-coded rulings.

A second aspect of the present disclosure provides a system comprising: a processor in communication with a memory, the processor configured to execute instructions in the memory to cause the system to: receive sensor data; determine a signal reliability factor for the received sensor data, wherein the signal reliability factor represents a statistical quality indication between the received sensor data and an expected value or an expected range of values; and associating the signal reliability factor with the received sensor data.

In accordance with the preceding aspect, the processor may be further configured to execute the instructions in the memory to cause the system to determine if the signal reliability factor satisfies criteria; and to discard the received sensor data or to use the received sensor data to generate one or more commands which are configured to control a central control system, depending on whether the signal reliability factor satisfies the criteria.

In accordance with the preceding aspect, the expected value or the expected range of values may be based on immediately preceding sensor data, the immediately preceding data being received at an antecedent time point with respect to a time point when the sensor data is received.

In accordance with the preceding aspect, the processor may be further configured to execute the instructions in the memory to cause the system to, in response to the signal reliability factor indicating that the received sensor data is incoherent with the immediately preceding sensor data, evaluate influence of the action performed by the external entity based on the signal reliability factor.

In accordance with the preceding aspect, the received sensor data may be first sensor data generated by a first sensor system, and the processor may be further configured to execute the instructions in the memory to cause the system to receive second sensor data from a second sensor system; and statistically infer the expected value or the expected range of values based on the second sensor data.

In accordance with the preceding aspect, the system is associated with a vehicle, and the processor may be further configured to execute the instructions in the memory to cause the system to determine a vehicle condition associated with the vehicle; and statistically infer the expected value or the expected range of values based on the vehicle condition.

In accordance with the preceding aspect, the processor may be further configured to execute the instructions in the memory to cause the system to determine the signal reliability factor by applying statistical rules to the received sensor data and the expected value or the expected range of values to generate the statistical quality indication, wherein the statistical rules include Bayesian rulings or position-coded rulings.

Non-limiting embodiments can be found in the independent and dependent claims and in the entire disclosure, wherein in the description and representation of the features is not always differentiated in detail between the different claim categories; In any case implicitly, the disclosure is always directed both to the method and to appropriately equipped motor vehicles (LIDAR Sensor Devices) and/or a corresponding computer program product.

### BRIEF DESCRIPTION OF THE DRAWINGS

The detailed description is described with reference to the accompanying figures. The use of the same reference number in different instances in the description and the figure may indicate a similar or identical item. The drawings are not necessarily to scale, emphasis instead generally being placed upon illustrating the principles of the present disclosure.

In the following description, various embodiments of the present disclosure are described with reference to the following drawings, in which:

FIG. 1 shows schematically an embodiment of the proposed to LIDAR Sensor System, Controlled LIDAR Sensor System and LIDAR Sensor Device;

FIG. 2 shows a method in accordance with various non-limiting embodiments;

FIGS. 3A and 3B show each a system in a schematic view in accordance with various non-limiting embodiments;

FIG. 4 shows a system and a signal path in a schematic view in accordance with various non-limiting embodiments.

### DETAILED DESCRIPTION OF EMBODIMENTS

### LIDAR Sensor System and LIDAR Sensor Device

The LIDAR Sensor System according to the present disclosure may be combined with a LIDAR Sensor Device for illumination of an environmental space connected to a light control unit.

The LIDAR Sensor System may comprise at least one light module. Said one light module has a light source and a driver connected to the light source. The LIDAR Sensor System further has an interface unit, in particular a hardware interface, configured to receive, emit, and/or store data signals. The interface unit may connect to the driver and/or to the light source for controlling the operation state of the driver and/or the operation of the light source.

The light source may be configured to emit radiation in the visible and/or the non-visible spectral range, as for example in the far-red range of the electromagnetic spectrum. It may be configured to emit monochromatic laser light. The light source may be an integral part of the LIDAR Sensor System as well as a remote yet connected element. It may be placed in various geometrical patterns, distance pitches and may be configured for alternating of color or wavelength emission or intensity or beam angle. The LIDAR Sensor System and/or light sources may be mounted such that they are moveable or can be inclined, rotated, tilted etc. The LIDAR Sensor System and/or light source may be configured to be installed inside a LIDAR Sensor Device (e.g. vehicle) or exterior to a LIDAR Sensor Device (e.g. vehicle). In particular, it is possible that the LIDAR light source or selected LIDAR light sources are mounted such or adapted to being automatically controllable, in some implementations remotely, in their orientation, movement, light emission, light spectrum, sensor etc.

The light source may be selected from the following group or a combination thereof: light emitting diode (LED), super-luminescent laser diode (LD), VSECL laser diode array.

In some embodiments, the LIDAR Sensor System may comprise a sensor, such as a resistive, a capacitive, an inductive, a magnetic, an optical and/or a chemical sensor. It may comprise a voltage or current sensor. The sensor may connect to the interface unit and/or the driver of the LIDAR light source.

In some embodiments, the LIDAR Sensor System and/or LIDAR Sensor Device comprise a brightness sensor, for example for sensing environmental light conditions in proximity of vehicle objects, such as houses, bridges, sign posts, and the like. It may be used for sensing daylight conditions and the sensed brightness signal may e.g. be used to improve surveillance efficiency and accuracy. That way, it may be enabled to provide the environment with a required amount of light of a predefined wavelength.

In some embodiments, the LIDAR Sensor System and/or LIDAR Sensor Device comprises a sensor for vehicle movement, position and orientation. Such sensor data may allow a better prediction, as to whether the vehicle steering conditions and methods are sufficient.

The LIDAR Sensor System and/or LIDAR Sensor Device may also comprise a presence sensor. This may allow to adapt the emitted light to the presence of another traffic participant including pedestrians in order to provide sufficient illumination, prohibit or minimize eye damage or skin irritation or such due to illumination in harmful or invisible wavelength regions, such as UV or IR. It may also be enabled to provide light of a wavelength that may warn or frighten away unwanted presences, e.g. the presence of animals such as pets or insects.

In some embodiments, the LIDAR Sensor System and/or LIDAR Sensor Device comprises a sensor or multi-sensor for predictive maintenance and/or operation of the LIDAR Sensor System and/or LIDAR Sensor Device failure.

In some embodiments, the LIDAR Sensor System and/or LIDAR Sensor Device comprises an operating hour meter. The operating hour meter may connect to the driver.

The LIDAR Sensor System may comprise one or more actuators for adjusting the environmental surveillance conditions for the LIDAR Sensor Device (e.g. vehicle). For instance, it may comprise actuators that allow adjusting for instance, laser pulse shape, temporal length, rise- and fall times, polarization, laser power, laser type (IR-diode, VCSEL), Field of View (FOV), laser wavelength, beam changing device (MEMS, DMD, DLP, LCD, Fiber), beam and/or sensor aperture, sensor type (PN-diode, APD, SPAD).

While the sensor or actuator has been described as part of the LIDAR Sensor System and/or LIDAR Sensor Device, it is understood, that any sensor or actuator may be an individual element or may form part of a different element of the LIDAR Sensor System. As well, it may be possible to provide an additional sensor or actuator, being configured to perform or performing any of the described activities as individual element or as part of an additional element of the LIDAR Sensor System.

In some embodiments, the LIDAR Sensor System and/or LIDAR Light Device further comprises a light control unit that connects to the interface unit.

The light control unit may be configured to control the at least one light module for operating in at least one of the following operation modes: dimming, pulsed, PWM, boost, irradiation patterns, including illuminating and non-illuminating periods, light communication (including C2C and C2X), synchronization with other elements of the LIDAR Sensor System, such as a second LIDAR Sensor Device.

The interface unit of the LIDAR Sensor System and/or LIDAR Sensor Device may comprise a gateway, such as a wireless gateway, that may connect to the light control unit. It may comprise a beacon, such as a Bluetooth™ beacon.

The interface unit may be configured to connect to other elements of the LIDAR Sensor System, e.g. one or more other LIDAR Sensor Systems and/or LIDAR Sensor Devices and/or to one or more sensors and/or one or more actuators of the LIDAR Sensor System.

The interface unit may be configured to be connected by any wireless or wireline connectivity, including radio and/or optical connectivity.

The LIDAR Sensor System and/or LIDAR Sensor Device may be configured to enable customer-specific and/or vehicle-specific light spectra. The LIDAR Sensor Device may be configured to change the form and/or position and/or orientation of the at least one LIDAR Sensor System. Further, the LIDAR Sensor System and/or LIDAR Sensor Device may be configured to change the light specifications of the light emitted by the light source, such as direction of emission, angle of emission, beam divergence, color, wavelength, and intensity as well as other characteristics like laser pulse shape, temporal length, rise- and fall times, polarization, pulse synchronization, pulse synchronization, laser power, laser type (IR-diode, VCSEL), Field of View (FOV), laser wavelength, beam changing device (MEMS, DMD, DLP, LCD, Fiber), beam and/or sensor aperture, sensor type (PN-diode, APD, SPAD).

In some embodiments, the LIDAR Sensor System and/or LIDAR Sensor Device may comprise a data processing unit. The data processing unit may connect to the LIDAR light driver and/or to the interface unit. It may be configured for data processing, for data and/or signal conversion and/or data storage. The data processing unit may advantageously be provided for communication with local, network-based or web-based platforms, data sources or providers, in order to transmit, store or collect relevant information on the light module, the road to be travelled, or other aspects connected with the LIDAR Sensor System and/or LIDAR Sensor Device.

In some embodiments, the LIDAR Sensor Device can encompass one or many LIDAR Sensor Systems that themselves can be comprised of infrared or visible light emitting modules, photoelectric sensors, optical components, interfaces for data communication, actuators, like MEMS mirror systems, computing and data storage devices, software and software databank, communication systems for communication with IoT, edge or cloud systems.

The LIDAR Sensor System and/or LIDAR Sensor Device can further include light emitting and light sensing elements that can be used for illumination purposes, like road lighting, or for data communication purposes, for example car-to-car, car-to-environment (for example drones, pedestrian, traffic signs, traffic posts etc.).

The LIDAR Sensor Device can further comprise one or more LIDAR Sensor Systems as well as other sensor systems, like optical camera sensor systems (CCD; CMOS), RADAR sensing system, and ultrasonic sensing systems.

The LIDAR Sensor Device can be functionally designed as vehicle headlight, rear light, side light, daytime running light (DRL), corner light etc. and comprise LIDAR sensing functions as well as visible illuminating and signaling functions.

The LIDAR Sensor System may further comprise a control unit (Controlled LIDAR Sensor System). The control unit may be configured for operating a management system. It is configured to connect to one or more LIDAR Sensor Systems and/or LIDAR Sensor Devices. It may connect to a data bus. The data bus may be configured to connect to an interface unit of an LIDAR Sensor Device. As part of the management system, the control unit may be configured for controlling an operating state of the LIDAR Sensor System and/or LIDAR Sensor Device.

The LIDAR Sensor Management System may comprise a light control system which may comprise any of the following elements: monitoring and/or controlling the status of the at least one LIDAR Sensor System and/or LIDAR Sensor Device, monitoring and/or controlling the use of the at least one LIDAR Sensor System and/or LIDAR Sensor Device, scheduling the lighting of the at least one LIDAR Sensor System and/or LIDAR Sensor Device, adjusting the light spectrum of the at least one LIDAR Sensor System and/or LIDAR Sensor Device, defining the light spectrum of the at least one LIDAR Sensor System and/or LIDAR Sensor Device, monitoring and/or controlling the use of at least one sensor of the at least one LIDAR Sensor System and/or LIDAR Sensor Device.

In some embodiments, the method for LIDAR Sensor System can be configured and designed to select, operate and control, based on internal or external data input, laser power, pulse shapes, pulse length, measurement time windows, wavelength, single wavelength or multiple wavelength approach, day and night settings, sensor type, sensor fusion, as well as laser safety functions according to relevant safety regulations.

The method for LIDAR Sensor Management System can be configured to initiate data encryption, data decryption and data communication protocols.

### LIDAR Sensor System, Controlled LIDAR Sensor System, LIDAR Sensor Management System and Software

In a Controlled LIDAR Sensor System according to the present disclosure, the computing device may be locally based, network based, and/or cloud-based. That means, the computing may be performed in the Controlled LIDAR Sensor System or on any directly or indirectly connected entities. In the latter case, the Controlled LIDAR Sensor System is provided with some connecting means, which allow establishment of at least a data connection with such connected entities.

In some embodiments, the Controlled LIDAR Sensor System comprises a LIDAR Sensor Management System connected to the at least one hardware interface. The LIDAR Sensor Management System may comprise one or more actuators for adjusting the surveillance conditions for the environment. Surveillance conditions may, for instance, be vehicle speed, vehicle road density, vehicle distance to other objects, object type, object classification, emergency situations, weather conditions, day or night conditions, day or night time, vehicle and environmental temperatures, and driver biofeedback signals.

The present disclosure further comprises an LIDAR Sensor Management Software. The present disclosure further comprises a data storage device with the LIDAR Sensor Management Software, wherein the data storage device is enabled to run the LIDAR Sensor Management Software. The data storage device may either comprise be a hard disk, a RAM, or other common data storage utilities such as USB storage devices, CDs, DVDs and similar.

The LIDAR Sensor System, in particular the LIDAR Sensor Management Software, may be configured to control the steering of Automatically Guided Vehicles (AGV).

In some embodiments, the computing device is configured to perform the LIDAR Sensor Management Software.

The LIDAR Sensor Management Software may comprise any member selected from the following group or a combination thereof: software rules for adjusting light to outside conditions, adjusting the light intensity of the at least one LIDAR Sensor System and/or LIDAR Sensor Device to environmental conditions, adjusting the light spectrum of the at least one LIDAR Sensor System and/or LIDAR Sensor Device to environmental conditions, adjusting the light spectrum of the at least one LIDAR Sensor System and/or LIDAR Sensor Device to traffic density conditions, adjusting the light spectrum of the at least one LIDAR Sensor System and/or LIDAR Sensor Device according to customer specification or legal requirements.

According to some embodiments, the Controlled LIDAR Sensor System further comprises a feedback system connected to the at least one hardware interface. The feedback system may comprise one or more sensors for monitoring the state of surveillance for which the Controlled LIDAR Sensor System is provided. The state of surveillance may for example, be assessed by at least one of the following: road accidents, required driver interaction, Signal-to-Noise ratios, driver biofeedback signals, close encounters, fuel consumption, and battery status.

The Controlled LIDAR Sensor System may further comprise a feedback software.

The feedback software may in some embodiments comprise algorithms for vehicle (LIDAR Sensor Device) steering assessment on the basis of the data of the sensors.

The feedback software of the Controlled LIDAR Sensor System may in some embodiments comprise algorithms for deriving surveillance strategies and/or lighting strategies on the basis of the data of the sensors.

The feedback software of the Controlled LIDAR Sensor System may in some embodiments of the present disclosure comprise LIDAR lighting schedules and characteristics depending on any member selected from the following group or a combination thereof: road accidents, required driver interaction, Signal-to-Noise ratios, driver biofeedback signals, close encounters, road warnings, fuel consumption, battery status, other autonomously driving vehicles.

The feedback software may be configured to provide instructions to the LIDAR Sensor Management Software for adapting the surveillance conditions of the environment autonomously.

The feedback software may comprise algorithms for interpreting sensor data and suggesting corrective actions to the LIDAR Sensor Management Software.

In some embodiments of the LIDAR Sensor System, the instructions to the LIDAR Sensor Management Software are based on measured values and/or data of any member selected from the following group or a combination thereof: vehicle (LIDAR Sensor Device) speed, distance, density, vehicle specification and class.

The LIDAR Sensor System therefore may have a data interface to receive the measured values and/or data. The data interface may be provided for wire-bound transmission or wireless transmission. In particular, it is possible that the measured values or the data are received from an intermediate storage, such as a cloud-based, web-based, network-based or local type storage unit.

Further, the sensors for sensing environmental conditions may be connected with or interconnected by means of cloud-based services, often also referred to as Internet of Things.

In some embodiments, the Controlled LIDAR Sensor System comprises a software user interface (UI), particularly a graphical user interface (GUI). The software user interface may be provided for the light control software and/or the LIDAR Sensor Management Software and/or the feedback software.

The software user interface (UI) may further comprise a data communication and means for data communication for an output device, such as an augmented and/or virtual reality display.

The user interface may be implemented as an application for a mobile device, such as a smartphone, a tablet, a mobile computer or similar devices.

The Controlled LIDAR Sensor System may further comprise an application programming interface (API) for controlling the LIDAR Sensing System by third parties and/or for third party data integration, for example road or traffic conditions, street fares, energy prices, weather data, GPS.

In some embodiments, the Controlled LIDAR Sensor System comprises a software platform for providing at least one of surveillance data, vehicle (LIDAR Sensor Device) status, driving strategies, and emitted sensing light.

In some embodiments, the LIDAR Sensor System and/or the Controlled LIDAR Sensor System can include infrared or visible light emitting modules, photoelectric sensors, optical components, interfaces for data communication, and actuators, like MEMS mirror systems, a computing and data storage device, a software and software databank, a communication system for communication with IoT, edge or cloud systems.

The LIDAR Sensor System and/or the Controlled LIDAR Sensor System can include light emitting and light sensing elements that can be used for illumination or signaling purposes, like road lighting, or for data communication purposes, for example car-to-car, car-to-environment.

In some embodiments, the LIDAR Sensor System and/or the Controlled LIDAR Sensor System may be installed inside the driver cabin in order to perform driver monitoring functionalities, such as occupancy-detection, eye-tracking, face recognition, drowsiness detection, access authorization, gesture control, etc.) and/or to communicate with a Head-up-Display HUD).

The software platform may cumulate data from one's own or other vehicles (LIDAR Sensor Devices) to train machine learning algorithms for improving surveillance and car steering strategies.

The Controlled LIDAR Sensor System may also comprise a plurality of LIDAR Sensor Systems arranged in adjustable groups.

The present disclosure further refers to a vehicle (LIDAR Sensor Device) with at least one LIDAR Sensor System. The vehicle may be planned and build particularly for integration of the LIDAR Sensor System. However, it is also possible, that the Controlled LIDAR Sensor System was integrated in a pre-existing vehicle. According to the present disclosure, both cases as well as a combination of these cases shall be referred to.

### Method for a LIDAR Sensor System

According to yet another aspect of the present disclosure, a method for a LIDAR Sensor System is provided, which comprises at least one LIDAR Sensor System. The method may comprise the steps of controlling the light emitted by the at least one LIDAR Sensor System by providing light control data to the hardware interface of the Controlled LIDAR Sensor System and/or sensing the sensors and/or controlling the actuators of the Controlled LIDAR Sensor System via the LIDAR Sensor Management System.

According to yet another aspect of the present disclosure, the method for LIDAR Sensor System can be configured and designed to select, operate and control, based on internal or external data input, laser power, pulse shapes, pulse length, measurement time windows, wavelength, single wavelength or multiple wavelength approach, day and night settings, sensor type, sensor fusion, as well as laser safety functions according to relevant safety regulations.

The method according to the present disclosure may further comprise the step of generating light control data for adjusting the light of the at least one LIDAR Sensor System to environmental conditions.

In some embodiments, the light control data is generated by using data provided by the daylight or night vision sensor.

According to some embodiments, the light control data is generated by using data provided by a weather or traffic control station.

The light control data may also be generated by using data provided by a utility company in some embodiments.

Advantageously, the data may be gained from one data source, whereas that one data source may be connected, e.g. by means of Internet of Things devices, to those devices. That way, data may be pre-analyzed before being released to the LIDAR Sensor System, missing data could be identified, and in further advantageous developments, specific pre-defined data could also be supported or replaced by “best-guess” values of a machine learning software.

In some embodiments, the method further comprises the step of using the light of the at least one LIDAR Sensor Device for example during the time of day or night when traffic conditions are the best. Of course, other conditions for the application of the light may also be considered.

In some embodiments, the method may comprise a step of switching off the light of the at least one LIDAR Sensor System depending on a predetermined condition. Such condition may for instance occur, if the vehicle (LIDAR Sensor Device) speed or a distance to another traffic object is lower than a pre-defined or required safety distance or safety condition.

The method may also comprise the step of pushing notifications to the user interface in case of risks or fail functions and vehicle health status.

In some embodiments, the method comprises analyzing sensor data for deducing traffic density and vehicle movement.

The LIDAR Sensor System features may be adjusted or triggered by way of a user interface or other user feedback data. The adjustment may further be triggered by way of a machine learning process, as far as the characteristics, which are to be improved or optimized are accessible by sensors. It is also possible that individual users adjust the surveillance conditions and or further surveillance parameters to individual needs or desires.

The method may also comprise the step of uploading LIDAR sensing conditions to a software platform and/or downloading sensing conditions from a software platform.

In at least one embodiment, the method comprises a step of logging performance data to an LIDAR sensing notebook.

The data cumulated in the Controlled LIDAR Sensor System may, in a step of the method, be analyzed in order to directly or indirectly determine maintenance periods of the LIDAR Sensor System, expected failure of system components or such.

According to another aspect, the present disclosure comprises a computer program product comprising a plurality of program instructions, which when executed by a computer system of a LIDAR Sensor System, cause the Controlled LIDAR Sensor System to execute the method according to the present disclosure. The disclosure further comprises a data storage device.

Yet another aspect of the present disclosure refers to a data storage device with a computer program adapted to execute at least one of a method for a LIDAR Sensor System or a LIDAR Sensor Device.

Autonomously driving vehicles need sensing methods that detect objects and map their distances in a fast and reliable manner. Light detection and ranging (LIDAR), sometimes called Laser Detection and Ranging (LADAR), Time of Flight measurement device (TOF), Laser Scanners or Laser Radar—is a sensing method that detects objects and maps their distances. The technology works by illuminating a target with an optical pulse and measuring the characteristics of the reflected return signal. The width of the optical-pulse can range from a few nanoseconds to several microseconds.

In order to steer and guide autonomous cars in a complex driving environment, it is adamant to equip vehicles with fast and reliable sensing technologies that provide high-resolution, three-dimensional information (Data Cloud) about the surrounding environment thus enabling proper vehicle control by using on-board or cloud-based computer systems.

For distance and speed measurement, a light-detection-and-ranging LIDAR Sensor Systems can be used. With LIDAR Sensor Systems, it is possible to quickly scan the environment and detect speed and direction of movement of individual objects (vehicles, pedestrians, static objects). LIDAR Sensor Systems are used, for example, in partially autonomous vehicles or fully autonomously driving prototypes, as well as in aircraft and drones. A high-resolution LIDAR Sensor System emits a (mostly infrared) laser beam, and further uses lenses, mirrors or micro-mirror systems, as well as suited sensor devices.

The disclosure relates to a LIDAR Sensor System for environment detection, wherein the LIDAR Sensor System is designed to carry out repeated measurements for detecting the environment, wherein the LIDAR Sensor System has an emitting unit (First LIDAR Sensing System) which is designed to perform a measurement with at least one laser pulse and wherein the LIDAR system has a detection unit (Second LIDAR Sensing Unit), which is designed to detect an object-reflected laser pulse during a measurement time window. Furthermore, the LIDAR system has a control device (LIDAR Data Processing System/Control and Communication System/LIDAR Sensor Management System), which is designed, in the event that at least one reflected beam component is detected, to associate the detected beam component on the basis of a predetermined assignment with a solid angle range from which the beam component originates. The disclosure also includes a method for operating a LIDAR Sensor System.

The distance measurement in question is based on a transit time measurement of emitted electromagnetic pulses. The electromagnetic spectrum should range from the ultraviolet via the visible to the infrared, including violet and blue radiation in the range from 405 to 480 nm. If these hit an object, the pulse is proportionately reflected back to the distance-measuring unit and can be recorded as an echo pulse with a suitable sensor. If the emission of the pulse takes place at a time to and the echo pulse is detected at a later time t1, the distance d to the reflecting surface of the object over the transit time ΔtA=t1−t0 can be determined according Eq.1.

$$d = Δ tAc / 2 \qquad Eq . 1$$

Since these are electromagnetic pulses, c is the value of the speed of light. In the context of this disclosure, the word electromagnetic comprises the entire electromagnetic spectrum, thus including the ultraviolet, visible and infrared spectrum range.

The LIDAR method is usefully working with light pulses which, for example, using semiconductor laser diodes having a wavelength between about 850 nm to about 1600 nm, which have a FWHM pulse width of 1 ns to 100 ns (FWHM=Full Width at Half Maximum). Also conceivable in general are wavelengths up to, in particular approximately, 8100 nm.

Furthermore, each light pulse is typically associated with a measurement time window, which begins with the emission of the measurement light pulse. If objects that are very far away are to be detectable by a measurement, such as, for example, objects at a distance of 300 meters and farther, this measurement time window, within which it is checked whether at least one reflected beam component has been received, must last at least two microseconds. In addition, such measuring time windows typically have a temporal distance from each other.

The use of LIDAR sensors is now increasingly used in the automotive sector. Correspondingly, LIDAR sensors are increasingly installed in motor vehicles.

The disclosure also relates to a method for operating a LIDAR Sensor System arrangement comprising a First LIDAR Sensor System with a first LIDAR sensor and at least one Second LIDAR Sensor System with a second LIDAR sensor, wherein the first LIDAR sensor and the second LIDAR sensor repeatedly perform respective measurements, wherein the measurements of the first LIDAR Sensor are performed in respective first measurement time windows, at the beginning of which a first measurement beam is emitted by the first LIDAR sensor and it is checked whether at least one reflected beam component of the first measurement beam is detected within the respective first measurement time window. Furthermore, the measurements of the at least one second LIDAR sensor are performed in the respective second measurement time windows, at the beginning of which a second measurement beam is emitted by the at least one second LIDAR sensor, and it is checked whether within the respective second measurement time window at least one reflected beam portion of the second measuring beam is detected. The disclosure also includes a LIDAR Sensor System arrangement with a first LIDAR sensor and at least one second LIDAR sensor.

A LIDAR (light detection and ranging) Sensor System is to be understood in particular as meaning a system which, in addition to one or more emitters for emitting light beams, for example in pulsed form, and a detector for detecting any reflected beam components, may have further devices, for example optical elements such as lenses and/or a MEMS mirror.

The oscillating mirrors or micro-mirrors of the MEMS (Micro-Electro-Mechanical System) system, in some embodiments in cooperation with a remotely located optical system, allow a field of view to be scanned in a horizontal angular range of e.g. 60° or 120° and in a vertical angular range of e.g. 30°. The receiver unit or the sensor can measure the incident radiation without spatial resolution. The receiver unit can also be spatial angle resolution measurement device. The receiver unit or sensor may comprise a photodiode, e.g. an avalanche photo diode (APD) or a single photon avalanche diode (SPAD), a PIN diode or a photomultiplier. Objects can be detected, for example, at a distance of up to 60 m, up to 300 m or up to 600 m using the LIDAR system. A range of 300 m corresponds to a signal path of 600 m, from which, for example, a measuring time window or a measuring duration of 2 us can result.

As already described, optical reflection elements in a LIDAR Sensor System may include micro-electrical mirror systems (MEMS) and/or digital mirrors (DMD) and/or digital light processing elements (DLP) and/or a galvo-scanner for control of the emitted laser beam pulses and/or reflection of an object-back-scattered laser pulses onto a sensor surface. Advantageously, a plurality of mirrors is provided. These may particularly be arranged in some implementations in the manner of a matrix. The mirrors may be individually and separately, independently of each other rotatable or movable.

The individual mirrors can each be part of a so-called micro mirror unit or “Digital Micro-Mirror Device” (DMD). A DMD can have a multiplicity of mirrors, in particular micro-mirrors, which can be rotated at high frequency between at least two positions. Each mirror can be individually adjustable in its angle and can have at least two stable positions, or with other words, in particular stable, final states, between which it can alternate. The number of mirrors can correspond to the resolution of a projected image, wherein a respective mirror can represent a light pixel on the area to be irradiated. A “Digital Micro-Mirror Device” is a micro-electromechanical component for the dynamic modulation of light.

Thus, the DMD can for example provide suited illumination for a vehicle low and/or a high beam. Furthermore, the DMD may also serve projection light for projecting images, logos, and information on a surface, such as a street or surrounding object. The mirrors or the DMD can be designed as a micro-electromechanical system (MEMS). A movement of the respective mirror can be caused, for example, by energizing the MEMS. Such micro-mirror arrays are available, for example, from Texas Instruments. The micro-mirrors are in particular arranged like a matrix, e.g. for example, in an array of 854×480 micro-mirrors, as in the DLP3030-Q1 0.3-inch DMP mirror system optimized for automotive applications by Texas Instruments, or a 1920×1080 micro-mirror system designed for home projection applications 4096×2160 Micro-mirror system designed for 4K cinema projection applications, but also usable in a vehicle application. The position of the micro-mirrors is, in particular, individually adjustable, for example with a clock rate of up to 32 kHz, so that predetermined light patterns can be coupled out of the headlamp by corresponding adjustment of the micro-mirrors.

In some embodiments, the used MEMS arrangement may be provided as a 1D or 2D MEMS arrangement. In a 1D MEMS, the movement of an individual mirror takes place in a translatory or rotational manner about an axis. In 2D MEMS, the individual mirror is gimballed and oscillates about two axes, whereby the two axes can be individually employed so that the amplitude of each vibration can be adjusted and controlled independently of the other.

Furthermore, a beam radiation from the light source can be deflection through a structure with at least one liquid crystal element, wherein one molecular orientation of the at least one liquid crystal element is adjustable by means of an electric field. The structure through which the radiation to be aligned is guided can comprise at least two sheet-like elements coated with electrically conductive and transparent coating material. The plate elements are in some embodiments transparent and spaced apart from each other in parallel. The transparency of the plate elements and the electrically conductive coating material allows transmission of the radiation. The electrically conductive and transparent coating material can at least partially or completely made of a material with a high electrical conductivity or a small electrical resistance such as indium tin oxide (ITO) and/or of a material with a low electrical conductivity or a large electrical resistance such as poly-3,4-ethylenedioxythiophene (PEDOT).

The generated electric field can be adjustable in its strength. The electric field can be adjustable in particular by applying an electrical voltage to the coating material or the coatings of the plate elements. Depending on the size or height of the applied electrical voltages on the coating materials or coatings of the plate elements formed as described above, differently sized potential differences and thus a different electrical field are formed between the coating materials or coatings.

Depending on the strength of the electric field, that is, depending on the strength of the voltages applied to the coatings, the molecules of the liquid crystal elements may align with the field lines of the electric field.

Due to the differently oriented liquid crystal elements within the structure, different refractive indices can be achieved. As a result, the radiation passing through the structure, depending on the molecular orientation, moves at different speeds through the liquid crystal elements located between the plate elements. Overall, the liquid crystal elements located between the plate elements have the function of a prism, which can deflect or direct incident radiation. As a result, with a correspondingly applied voltage to the electrically conductive coatings of the plate elements, the radiation passing through the structure can be oriented or deflected, whereby the deflection angle can be controlled and varied by the level of the applied voltage.

Furthermore, a combination of white or colored light sources and infrared laser light sources is possible, in which the light source is followed by an adaptive mirror arrangement, via which radiation emitted by both light sources can be steered or modulated, a sensor system being used for the infrared light source intended for environmental detection. The advantage of such an arrangement is that the two light systems and the sensor system use a common adaptive mirror arrangement. It is therefore not necessary to provide for the light system and the sensor system each have their own mirror arrangement. Due to the high degree of integration space, weight and in is particular costs can be reduced.

In LIDAR systems, differently designed transmitters and receiver concepts are also known in order to be able to record the distance information in different spatial directions. Based on this, a two-dimensional image of the environment is then generated, which contains the complete three-dimensional coordinates for each resolved spatial point. The different LIDAR topologies can be abstractly distinguished based on how the image resolution is displayed. Namely, the resolution can be represented either exclusively by an angle-sensitive detector, an angle-sensitive emitter, or a combination of both. A LIDAR system, which generates its resolution exclusively by means of the detector, is called a Flash LIDAR. It includes of an emitter, which illuminates as homogeneously as possible the entire field of vision. In contrast, the detector in this case includes of a plurality of individually readable and arranged in a matrix segments or pixels. Each of these pixels is correspondingly assigned a solid angle range. If light is received in a certain pixel, then the light is correspondingly derived from the solid angle region assigned to this pixel. In contrast to this, a raster or scanning LIDAR has an emitter which emits the measuring pulses selectively and in particular temporally sequentially in different spatial directions. Here a single sensor segment is sufficient as a detector. If, in this case, light is received by the detector in a specific measuring time window, then this light comes from a solid angle range into which the light was emitted by the emitter in the same measuring time window.

To improve Signal-to-Noise Ratio (SNR), a plurality of the above-described measurements or single-pulse measurements can be netted or combined with each other in a LIDAR Sensor System, for example to improve the signal-to-noise ratio by averaging the determined measured values.

The radiation emitted by the light source is in some embodiments infrared (IR) radiation emitted by a laser diode in a wavelength range of 600 nm to 850 nm. However, wavelengths up to 1064 nm, up to 1600 nm, up to 5600 nm or up to 8100 nm are also possible. The radiation of the laser diode can be emitted in a pulse-like manner with a frequency between 1 kHz and 1 MHZ, in some implementations with a frequency between 10 KHz and 100 kHz. The laser pulse duration may be between 0.1 ns and 100 ns, in some implementations between 1 ns and 2 ns. As a type of the IR radiation emitting laser diode, a VCSEL (Vertical Cavity Surface Emitting Laser) can be used, which emits radiation with a radiation power in the “milliwatt” range. However, it is also possible to use a VECSEL (Vertical External Cavity Surface Emitting Laser), which can be operated with high pulse powers in the wattage range. Both the VCSEL and the VECSEL may be in the form of an array, e.g. 15×20 or 20×20 laser diodes may be arranged so that the summed radiation power can be several hundred watts. If the lasers pulse simultaneously in an array arrangement, the largest summed radiation powers can be achieved. The emitter units may differ, for example, in their wavelengths of the respective emitted radiation. If the receiver unit is then also configured to be wavelength-sensitive, the pulses can also be differentiated according to their wavelength.

It is an object of the disclosure to propose improved components for a LIDAR Sensor System and/or to propose improved solutions for a LIDAR Sensor System and/or for a LIDAR Sensor Device and/or to propose improved methods for a LIDAR Sensor System and/or for a LIDAR Sensor Device.

The object is achieved according to the features of the independent claims. Further aspects of the disclosure are given in the dependent claims and the following description.

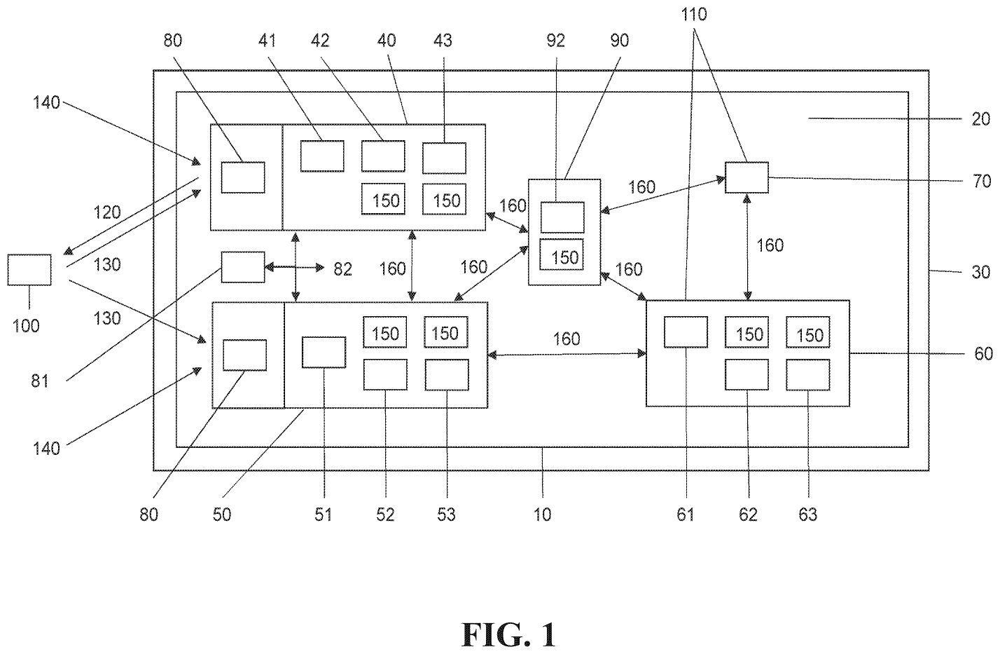

FIG. 1 shows schematically an embodiment of the proposed LIDAR Sensor System, Controlled LIDAR Sensor System and LIDAR Sensor Device.

The LIDAR Sensor System 10 comprises a First LIDAR Sensing System 40 that may comprise a Light Source 42 configured to emit electro-magnetic or other radiation 120, in particular a continuous-wave or pulsed laser radiation in the blue and/or infrared wavelength range, a Light Source Controller 43 and related Software, Beam Steering and Modulation Devices 41, in particular light steering and reflection devices, for example Micro-Mechanical Mirror Systems (MEMS), with a related control unit 150, Optical components 80, for example lenses and/or holographic elements, a LIDAR Sensor Management System 90 configured to manage input and output data that are required for the proper operation of the First LIDAR Sensing System 40.

The First LIDAR Sensing System 40 may be connected to other LIDAR Sensor System devices, for example to a Control and Communication System 70 that is configured to manage input and output data that are required for the proper operation of the First LIDAR Sensor System 40.

The LIDAR Sensor System 10 may include a Second LIDAR Sensing System 50 that is configured to receive and measure electromagnetic or other radiation, using a variety of Sensors 52 and Sensor Controller 53.

The Second LIDAR Sensing System may comprise Detection Optics 82, as well as Actuators for Beam Steering and Control 51.

The LIDAR Sensor System 10 may further comprise a LIDAR Data Processing System 60 that performs Signal Processing 61, Data Analysis and Computing 62, Sensor Fusion and other sensing Functions 63.

The LIDAR Sensor System 10 may further comprise a Control and Communication System 70 that receives and outputs a variety of signal and control data 160 and serves as a Gateway between various functions and devices of the LIDAR Sensor System 10.

The LIDAR Sensor System 10 may further comprise one or many Camera Systems 81, either stand-alone or combined with another Lidar Sensor System 10 component or embedded into another Lidar Sensor System 10 component, and data-connected to various other devices like to components of the Second LIDAR Sensing System 50 or to components of the LIDAR Data Processing System 60 or to the Control and Communication System 70.

The LIDAR Sensor System 10 may be integrated or embedded into a LIDAR Sensor Device 30, for example a housing, a vehicle, a vehicle headlight.

The Controlled LIDAR Sensor System 20 is configured to control the LIDAR Sensor System 10 and its various components and devices, and performs or at least assists in the navigation of the LIDAR Sensor Device 30. The Controlled LIDAR Sensor System 20 may be further configured to communicate for example with another vehicle or a communication network and thus assists in navigating the LIDAR Sensor Device 30.

As explained above, the LIDAR Sensor System 10 is configured to emit electro-magnetic or other radiation in order to probe the environment 100 for other objects, like cars, pedestrians, road signs, and road obstacles. The LIDAR Sensor System 10 is further configured to receive and measure electromagnetic or other types of object-reflected or object-emitted radiation 130, but also other wanted or unwanted electromagnetic radiation 140, in order to generate signals 110 that can be used for the environmental mapping process, usually generating a point cloud that is representative of the detected objects.

Various components of the Controlled LIDAR Sensor System 20 use Other Components or Software 150 to accomplish signal recognition and processing as well as signal analysis. This process may include the use of signal information that come from other sensor devices.

Vehicles (e.g., automobiles) are becoming more and more autonomous or automated (e.g., capable of performing various functions, such as driving, with minimal human assistance). A vehicle may be or will be configured to navigate an environment with little or finally without any direct or indirect human assistance. The level of autonomy of a vehicle may be described or determined by the SAE-level of the vehicle (e.g., as defined by the Society of Automotive Engineers (SAE), for example in SAE J3016-2018: Taxonomy and definitions for terms related to driving automation systems for on-road motor vehicles). The SAE-level may have a value ranging from level 0 (e.g., substantially no driving automation) to level 5 (e.g., full driving automation).

For implementing the desired autonomous or automated functions a plurality of sensors may be provided (e.g., in a vehicle), such as cameras (e.g., night and day vision cameras), ultrasound sensors (e.g., ultrasound emitting and sensing systems), inertial sensors, LIDAR and/or RADAR environmental scanning and detection systems, and the like. The sensor data (e.g., output data from the sensors or sensor systems) may be analyzed in an intelligent way. By way of example, sensor signals may be pre-processed by the respective sensor system (e.g., by the respective sensor device). Additionally or alternatively, sensor signals may be processed by one or more systems or devices (e.g., one or more processors) of the vehicle, such as a Board-Control-System (BCU), a Board Computer, Data Analysis, Handling and Storage Devices, and the like. Illustratively, sensor data may be determined by the (e.g., processed) sensor signals.

Sensor data analysis may be assisted by intelligent sensor fusion (e.g., by merging data from multiple sensors or sensor systems). Sensor data may also be analyzed with respect to object recognition and object classification. Camera image recognition and classification analysis, for example, may also play an important role, leading to data points that may subsequently be used to define and execute proper vehicle control commands. These are areas where Artificial Intelligence Methods may be applied.

Traffic safety may rely on both safety and security aspects. The safety and security aspects may be related to an accurate and reliable operation of the above-mentioned sensor and data analysis systems. Safety aspects may be (e.g., negatively) influenced by passive adversaries, such as functional system safety features. Functional system safety features may include, for example, breakdown, failure, or any other abnormality of a system component (e.g. due to production issues or adverse conditions during runtime, such as mechanical shocks, thermal load and the like). Security aspects may be (e.g., negatively) influenced by active adversaries, for example by third parties. Security aspects may be influenced, for example, by cyber-attacks targeting Data Integrity, Data Authenticity, Data Availability and/or Data Confidentiality. It may be desirable to coordinate the development of safety and security design frameworks, such that they may complement each other.

Such complex tasks and such complex measurement and analysis procedures may be prone to errors, malfunctions and/or adversarial attacks (e.g., sophisticated and/or brute force adversarial attacks).

Various embodiments may be related to a method and various embodiments may be related to a device for providing reliable and robust sensor data. The method and/or the device may be configured to provide sensor data that are robust against sensor malfunctions, in particular against adversarial attacks (e.g., to remedy or at least reduce the impact of adversarial attacks). Illustratively, the method and/or the device may be configured to provide reliable (e.g., safe) and robust control of a vehicle (e.g., a vehicle with autonomous driving capabilities).

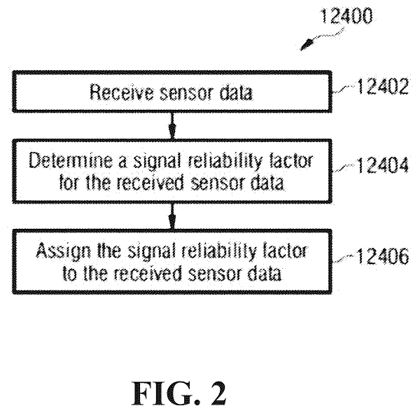

In the context of the present application, for example in relation to FIG. 2 to FIG. 4, the term “sensor system” may be used to describe a system configured to provide (e.g., to generate) sensor data. A sensor system may be a system including one or more sensors configured to generate one or more sensor signals. The sensor data may be provided from the one or more sensor signals. The features and/or the actions described herein in relation to a sensor system may apply accordingly also to a sensor, e.g. to the one or more sensors of a sensor system.

An example of adversarial attack (e.g., a possible attack to mode) may be a brute force attack on a sensor system (e.g., on the emitting and/or sensing parts, e.g. on the emitter and/or receiver path). By way of example, a camera system may be negatively affected by a visible or infra-red light (e.g., a laser flash) pointed towards a camera. A camera system (e.g., including a night vision camera) may also be affected by overexposure to a is white light flash or infra-red flash. As another example, an ultrasound system (e.g., an ultrasound sensing system) may be negatively affected by a pointed ultrasonic distortion signal, leading for example to jamming and spoofing effects. An ultrasound system may also be prone to errors or attacks due to ultrasound absorbing materials, which may lead to false negatives (e.g., to wrong or failed detection or identification of an object). As a further example, a RADAR system may be attacked by means of a RADAR distortion beam (e.g., a mm-wave RADAR distortion beam) directed onto a RADAR sensor (e.g., onto a RADAR sensing module). As a further example, a LIDAR system may be induced into error in case an adversarial system (e.g., a preceding vehicle) sprays a disturbing agent (e.g., water mist or smoke) in the surroundings of the LIDAR system. A LIDAR system may also be negatively affected by infrared light (e.g., a laser flash) or an overexposure to infra-red light (e.g., a laser flash). A LIDAR system may also be induced into error in case an object (e.g., a vehicle or a traffic object, such as a traffic sign) is covered (e.g., painted) with a coating or a material configured to reflect or absorb infra-red light (e.g., a highly reflecting or absorbing infra-red reflective coating or material). Such coating or material may cause the LIDAR system to detect and/or identify an uncommon object, due to the increased or suppressed signal strength with respect to a standard object (e.g., a non-altered vehicle or traffic object).

Another possible type of brute force attack may be a drone attack. A drone or another controllable moving object may move (e.g., fly) intentionally in the proximity of a sensor system (e.g., in the proximity of a vehicle, for example in front of the vehicle, or at the rear, or at the sides, or on top of the vehicle). The sudden appearance of the drone may lead to an abrupt (and potentially dangerous) vehicle reaction.

A brute force attack may thus lead to false positives (e.g., the detection or identification of an object not actually present), false negatives (e.g., the failed detection or identification of an object), or system malfunctions. A brute force attack may thus affect a broad variety of functions of an Advanced Driver Assistance System (ADAS), such as adaptive cruise control, collision avoidance, blind spot detection, lane departure warning, traffic sign recognition, parking assistance, and the like. A brute force attack may also affect vehicle control functions in (e.g., fully or partially) autonomous driving situations, such as route planning, route adaption emergency maneuvers, and the like.

Effects same or similar to the effects provided by a brute force attack may also be caused by natural events (in other words, by natural or ambient conditions). Such natural events may lead to system malfunctions (e.g., to system fail functions). As an example, a camera system or a LIDAR system may be exposed to too much sun light or to an excessive level of scattered infra-red radiation.

Another example of adversarial attack may be a sophisticated adversarial attack (or attack method). Such attack may be based, for example, on object recognition, image recognition and manipulations.

Methods of sophisticated attack may be, for example, image perturbation and lenticular lens effects. This may be the case, in particular, for sensor systems using Machine Learning (ML) or Artificial Intelligence (AI) methods that rely on supervised or unsupervised learning algorithms (e.g., deep neural learning algorithms). Such underlying algorithms may be prone to such intentional (e.g., sophisticated) attack.

A sophisticated adversarial attack may be defined or described as White Box attack or as Black Box attack. In a White Box attack (also referred to as White Box attack mode), the system (e.g., the sensor system) to be attacked and its functionalities is/are known and the behavior studied (for example, by reverse engineering and testing). Thus, the adversarial attack may be “custom-made” and tailored towards a specific attack scenario. In a Black Box attack (also referred to as Black Box attack mode), the inner functioning of a system to be attacked (e.g., of a used Machine Learning (ML) system) is not known and the attack may be based, for example, on trial-and-error attempts, trying to cause perturbations that lead to misdetection of images or to misleading object identification (e.g., categorization).

By way of example, a camera image recognition system may analyze an image including a captured text message or symbol. The text message or symbol may be, for example, exhibited by a preceding vehicle (e.g., word or visual messages like STOP, Follow Me, Do Not Follow Me, BREAK, Hazardous Goods, and the like). The text message or symbol may be or may represent, for example, a road sign (e.g., a traffic sign), such as a STOP sign, a Crossing Sign, and the like. The text message or symbol may be associated with specific road users, such as a logo of a wheelchair, pedestrians and the like. In case of an adversarial attack, the picture analyzing part (e.g., the image analyzing part) of a camera image processing system may be led to falsely interpret an intentionally modified text message and/or symbol (e.g., to falsely interpret a false text or symbol as being authentic).

This incorrect interpretation may lead to wrong or even dangerous vehicle control actions.

As another example, a vehicle (e.g., a preceding car, a bicycle, etc.) or another object may light up its exterior (e.g., the chassis or the windows of the vehicle) with signals using traffic-coded colors (e.g., red, yellow, green). Said vehicle or object may also emit a blinking light signal to resemble, for example, a yellow indicator signal, or a (e.g., changing) traffic light, or a police warning flash. Said vehicle or object may perform said actions with the intention of fooling a camera image processing system (e.g., a camera picture interpreting system). Additionally or alternatively, said vehicle or object may flash a coded signal that may be understood by a sensor system, e.g. by the vehicle image recognition system, and may lead to an aberrant behavior.

As another example, another traffic participant (e.g., a vehicle or a pedestrian) may project visual indications onto the road (e.g., a symbol, a text message, traffic-specific information, and the like). Said visual indications may lead to an erroneous vehicle behavior if taken (e.g., interpreted) as reliable input (e.g., as authentic input).

As another example, a manipulated image may be used for a sophisticated adversarial attack. Such manipulated image may be, for example, attached to a traffic sign, or to a non-traffic sign, or it may replace a traffic sign. By way of example, an object (e.g., a street sign or a traffic sign) may be plastered with misleading stickers that may cause only minor perturbations in the real world, but that may lead to wrong object identification (e.g., when using conventional, non-optimized, neural networks). As another example, a preceding vehicle may display pixel patterns of an otherwise benign image, manipulated to fool the image recognition system of another vehicle.

Thus, Advanced Driver Assistance System (ADAS) functionalities and other assisting vehicle or self-driving functions may be affected or compromised by a variety of factors. Such factors may include hardware defects, software malfunctions, contradicting information, no solution situations (e.g., in case computing takes too long, or in case a problem may be mathematically unsolvable), adversarial attacks (software, hardware, (multi)-sensor attacks), and the like. In this context, a vehicle with automated driving capabilities may be especially vulnerable to such factors and scenarios, thus leading to situations potentially detrimental to traffic safety.

A possible approach to the above-mentioned problems may include the use of Bayesian belief networks using rule-based inferencing to mechanisms configured to interpret retrieved data within the situational context to support event and alert generation for cyber threat assessment and prediction. However, such an approach may be difficult to handle (due to the high complexity) and may not secure a system against designed (e.g., tailored) adversarial attacks. Another approach may include using forward and is backward processing techniques of an attack image leading to a self-learning image classification network. However, such an approach may require high computing power and may have limitations related to the required computing time. Another approach may include providing a system used in an autonomous vehicle that detects an erroneously working vehicle control system, neutralizes its output, isolates such device from the vehicle's communication system and replaces it with another (e.g., uncompromised) vehicle control system. However, such an approach may be quite complex and may require a redundancy of control elements. Another approach may include comparing aggregated sensor data by performing encoding-decoding processes and comparing statistical deviation leading to contextual aggregated sensor data representation. Such sensor data representations may be compared with scene mapping information provided by a scene contextualizer. However, such an approach may require a massive use of computing power and data communication between cloud and edge computing devices leading to high system latencies making it practically unusable for real world requirements for safe autonomous driving.

Various embodiments may be directed to a method and various embodiments may be directed to a device provided to remedy or at least reduce the effects of various factors that may affect a vehicle, for example a vehicle with automated driving capabilities (e.g., the effects of the factors that may affect one or more sensor systems of the vehicle or of a sensor device, e.g. that may affect the reliability of sensor data). As an example, the method and/or the device may be provided to overcome or at least counteract and remedy some of the adversarial effects caused by an undesired or targeted adversarial attack. An adversarial attack may be understood as an action performed by an external entity (e.g., vehicle-external or sensor system-external, such as another vehicle, a pedestrian, a drone, a static object, etc.). Said action may be configured to negatively influence (or at least to attempt to negatively influence) the generation and/or analysis of sensor data (e.g., provided by an attacked sensor system or in an attacked vehicle).

In various embodiments, a vehicle (e.g., an autonomously driving vehicle) may have access to or it may be provided with position data (in other words, location data). The position data may describe or represent information about the current position (in other words, the current location or the current coordinates, e.g. GNSS/GPS coordinates) of the vehicle, and/or about the relative position of the vehicle with respect to another (e.g., static or moving) object. As an example, the vehicle may include or may have access to a Global Navigation Satellite System (GNSS) and/or a Global Positioning System (GPS) (e.g., it may include or have access to a GNSS and/or GPS communication system or module). Additionally or alternatively, the vehicle may have access to traffic and environment mapping data and/or data provider. By way of example, the vehicle may have access to GPS-coded Traffic Maps (TRM), Traffic Density Maps (TDM) and/or Traffic Density Probability Maps (TDPM) and/or Traffic Event Maps (TEM). Illustratively, the position data may be GPS data. By way of example, the vehicle may have access to intelligent driving methods (e.g., to an intelligent navigation system), e.g. information derived from previous vehicle trips along the same roads or areas.

The vehicle (e.g., a data processing system of the vehicle, for example including one or more processors) may be configured to determine (e.g., derive or calculate) positively known reference data from said position data. The vehicle may be configured to determine position-coded data or position-coded information (also referred to as GPS-coded data, or GPS-coded information) from the position data. Illustratively, based on the knowledge of the (e.g., current) location, the vehicle may be configured to determine (or make predictions on) the environment surrounding the vehicle (for example, an expected traffic or driving situation, e.g. based on whether the vehicle is located in a city or in the countryside).

In various embodiments, the vehicle (e.g., the data processing system of the vehicle or of a sensor device) may be configured to assign the position-coded information to predefined location selective categories (LSC), e.g. described by or associated with an integer number (e.g., LSCa, a=1, 2, . . . , m). The predefined location selective categories (LSC) may describe or represent a location where the vehicle is (e.g., currently) located, such as a parking lot, an urban environment, a motorway, an interstate, an off-road and the like. The predefined location selective categories (LSC) may also describe or represent information related to the location where the vehicle is located (e.g., a speed limit, an expected behavior of other vehicles, and the like).

In various embodiments, the vehicle (e.g., the data processing system) may be configured to assign the position-coded information to predefined environmental settings (ES), e.g. described by or associated with an integer number (e.g., ESb, b=1, 2, . . . , n). The environmental settings (ES) may include, for example, current day and time, time zone, weather, road conditions, other location-based traffic map information, (e.g., expected) traffic density and the like. Illustratively, the environmental settings (ES) may describe or represent information related to factors (e.g., vehicle-external factors) that may affect the driving of a vehicle.

In various embodiments, the vehicle (e.g., the data processing system) may have access to vehicle-specific (e.g., vehicle-related or vehicle-internal) information, e.g. positively known information about one or more properties or features of the vehicle. Said vehicle-specific information may be referred to as Driving Status (DS) or Driving Status data, e.g. described by or associated with an integer number (e.g., DSc, c=1, 2, . . . , p). The Driving Status (DS) may include, for example, an occupancy of the vehicle (e.g., the current number of occupants), vehicle loading, vehicle type, driving history, autonomy level (e.g., SAE level, for example from level 0 to level 5), driver identification data, driver biofeedback data, and the like. The Driving Status (DS) may be position-coded (e.g., GPS-coded). As an example, the driver biofeedback data may be GPS-coded (e.g., the behavior of the driver may be expected to vary depending on the location of the vehicle). Illustratively, the Driving Status (DS) may describe or represent information related to other factors (e.g., vehicle-internal factors) that may affect the driving of a vehicle.

The combination of one or more of the settings and/or status information (e.g., the location selective categories, the environmental settings, and the driving status) may be referred to as a vehicle condition (or vehicle scenario). Illustratively, a vehicle condition may describe one or more factors (e.g., location related, vehicle related, and/or environment related factors) that may affect the driving of a vehicle (and/or that may affect or be relevant for the functioning of one or more sensor systems).

In various embodiments, the various settings, e.g. the various information describing the current vehicle condition or scenario, may be combined (e.g., stored) in a General Setting Matrix (GSM). The General Setting Matrix (GSM) may be stored into and retrieved from a non-transitory storage medium (e.g., a memory). The non-transitory storage medium may be included in the vehicle, or the vehicle (e.g., the data processing system) may have access to the non-transitory storage medium, for example via a communication interface. Illustratively, the General Setting Matrix may be included in the data processing system.

The General Setting Matrix (GSM) may store predefined information for each of these settings (or combination of settings) about which to sensor data are to be prioritized (in what order), for example in case of sensor malfunction or aberrant behavior. The General Setting Matrix (GSM) may store a configuration for one or more sensors or sensor systems (e.g., included in the vehicle) associated with a respective vehicle condition (e.g., with the respective settings, e.g. with respective location selective categories, is environmental settings, and driving status, and/or with a respective combination thereof). The General Setting Matrix (GSM) may store a hierarchy (e.g., a level of relevance) for the one or more sensor systems associated with a respective vehicle condition. Illustratively, the General Setting Matrix (GSM) may store data (e.g., setting data) describing which sensor systems (or which combination) to use (or to prioritize) for each vehicle condition.

In various embodiments, the General Setting Matrix (GSM) may store a sensor fusion priority associated with each vehicle condition, e.g. the General Setting Matrix (GSM) may store a plurality of sensor fusion priorities, each associated with a respective vehicle condition. Illustratively, for each vehicle condition (e.g., for each setting), a preferred sensor fusion approach may be specified. The sensor fusion priority may describe which sensor systems (or which combination) to use (e.g., together) in the respective vehicle condition. By way of example, in an off-road condition, camera sensor data and LIDAR sensor data may be prioritized. As another example, RADAR and LIDAR sensor data fusion may be prioritized in a motorway or interstate condition. As a further example, in a parking lot situation, ultrasound sensor data in combination with camera data may be prioritized (e.g., it may be the preferred input for sensor fusion). As a further example, during inclement weather, LIDAR and RADAR sensor data may be the preferred input data for sensor fusion. The prioritized sensor data may then be used for subsequent processing (e.g., image recognition) and vehicle control (e.g., vehicle steering). The number of sensor systems used (e.g., how many LIDAR sensing devices, how many RADAR systems, etc.) and their combination may be adjusted depending on the actual vehicle condition. A vehicle may then be configured to use the (at least partially GPS-coded) sensor data for vehicle guidance.

In various embodiments, the coherence (e.g., the correlation) of the sensor data with expected sensor data (e.g., with an expected value and/or an expected range of the sensor data) may be determined. Illustratively, it may be determined whether a sensor signal is coherent with an expected sensor signal (e.g., whether a sensor output is coherent with an expected sensor output). Based on the determined coherence (e.g., on a determined signal reliability factor) a decision about whether to use or disregard (in other words, discard) the sensor data may be taken.

By way of example, a sensor system (e.g., prioritized or not prioritized) may receive a measurement signal (e.g., may generate a sensor signal and/or sensor data) that does not correlate with an expected output and/or with a predefined or expected range for the output. In this case, the output data (e.g., the incoherent sensor data) may be disregarded. Sensor data (e.g., reference sensor data) to be used may be specified (e.g., stored) in the General Setting Matrix (and retrieved therefrom). Illustratively, the General Setting Matrix (GSM) may store sensor data that may be used to replace the incoherent sensor data (e.g., in that specific vehicle condition).

The expected output and/or output range may be based (e.g., determined), for example, on immediately preceding data (e.g., on a sensor signal or sensor data generated at a previous time point, e.g. thirty seconds before, one minute before, etc.). The immediately preceding data may be the sensor data generated by the same sensor system immediately before the sensor data that are being evaluated.

As another example, a sensor system (e.g., prioritized or not prioritized) may provide no measurement signal (e.g., no sensor signal or no sensor data), e.g. due to malfunction. Illustratively, a sensor system may output a measurement signal (e.g., a sensor signal or sensor data) that does not correlate with the expected output and/or output range in such a way that no measurement signal is provided, e.g. because of malfunction. In this case, the output data (“zero values”, indicating for example that no object is present in an evaluated angular segment) may be disregarded. Sensor data may be used as specified by the General Setting Matrix (GSM).

As a further example, a combination of sensor systems (e.g., is prioritized or not prioritized) may provide a measurement signal (e.g., may generate a sensor signal and/or sensor data) that does not correlate with an expected output and/or output range. In this case, the output data may be disregarded. Sensor data (e.g., associated with that combination of sensor systems) may be used as specified by the General Setting Matrix (GSM).

In various embodiments, in case the General Setting Matrix (GSM) does not store (e.g., does not list) further specifications or instructions (e.g., further or alternative sensor data to be used), an emergency signal (or warning signal) may be generated (e.g., the General Setting Matrix (GSM) may provide a GSM-specific emergency signal). The emergency signal may describe one or more emergency actions or commands to be undertaken or executed.

Illustratively, the emergency signal may be used for further vehicle guidance. By way of example, in a parking lot situation, an immediate brake-signal may be provided. As another example, in a motorway situation a warning light may be flashed while the vehicle is cautiously steered towards the emergency lane. Thus, situations that may lead to sensor malfunction and/or to aberrant (e.g., incoherent) sensor data (e.g., output data), for example caused by an adversarial (e.g., brute force) attack, may be handled.

In various embodiments, the coherence of (e.g., first) sensor data generated by a first sensor system may be determined (e.g., evaluated) in relation with (e.g., second) sensor data generated by a second sensor system (e.g., an expected value for the first sensor data may be determined based on the second sensor data). Illustratively, sensor data from at least two sensor systems (e.g., from at least two sensors) may be combined, and their synchronicity and logical coherence may be compared. This approach may be effective, for example, to remedy or reduce the effect of a sophisticated attack. A sophisticated attack may not disturb the sensor measurement process per se but may manipulate it in such a way that a sensor receives input data (e.g., corrupted or perturbed input data) that lead to a different result (e.g., to different sensor data) compared with an unperturbed sensor input situation. As an example, a traffic road sign may be manipulated to show a STOP sign instead of an intended speed limit. A sophisticated attack (or attacker) may intentionally display a visual indication (e.g., a text message, a sign or a logo) that does not reflect the current traffic situation properly. The visual indication may be displayed, for example, on the back of a preceding vehicle, or projected onto the street. As an example, a STOP sign or a traffic jam warning message may be projected onto the street, while the traffic is actually flowing smoothly. Thus, determining the coherence of sensor data from at least two sensor systems may provide the effect of determining whether one of the sensor systems has been attacked (e.g., fooled).

In various embodiments, the coherence of the sensor data may be determined based on one or more position-coded rulings data (e.g., on GPS-coded rulings). Illustratively, the expected value for the sensor data may be determined (e.g., predicted) based on the position-coded rulings. The position-coded rulings may be included in (or may be described by) the location selective category. Logical coherence may be based on GPS-coded data sets. Additionally or alternatively, the coherence of the sensor data may be determined according to one or more Bayesian rulings.

By way of example, in case the vehicle is on an interstate, the current position data may specify parameters for the ‘interstate’ condition (e.g., the current location selective category may describe an ‘interstate’ condition). In this setting (e.g., in this vehicle condition), certain combinations of traffic signs or other traffic regulations may be determined as admissible or not admissible. As an example, it may be determined that a traffic speed sign (wrongly) displays a way too high-speed limit. As another example, it may be determined that a TURN RIGHT sign is placed in a location where no right turn can be made (e.g., as indicated by the position data, e.g. by a GPS map). As another example, a camera may interpret a STOP sign but another sensor system (or all other sensor systems) indicates a smoothly flowing traffic situation or an otherwise undisturbed environment. As a further example, a camera may not recognize any pedestrian (e.g., during the day) in a city downtown area (e.g., due to the effect of an adversarial attack). In these cases, another prioritization (or other sensor data) may be determined (and used), e.g. based on the data stored in the General Setting Matrix. Illustratively, a prioritization (e.g., an instant prioritization) of other preferred sensor data (e.g., sensor data sets) or other default values (e.g., enter into safety mode) may be provided.

Illustratively, one or more position-coded (e.g., GPS-coded) rulings may be provided or determined (e.g., from or associated with the location selective category (LSC)). The one or more position-coded rulings may describe certain combinations of commands (e.g., traffic commands) that are allowed or allowable in the current scenario (e.g., in the current vehicle condition). Sensor data that are not consistent (e.g., coherent) with said one or more rulings may be disregarded (e.g., the individual or combined sensor inputs may be disregarded) or at least questioned. A confidentiality value for the sensor system (or the sensor data) may be determined, for example ranging from 0 to 1, wherein 0 may indicate that it may be very unlikely that an attack has occurred, for example a sophisticated attack, and 1 may indicated that it may be very likely that an attack has occurred.

In various embodiments, the determination of the (e.g., logical) coherence of the sensor data may be provided by a module of the vehicle or of a sensor device (e.g., a Logical Coherence Module, LCM). The Logical Coherence Module (LCM) may be configured to determine a signal reliability factor for the sensor data. The signal reliability factor may describe the (e.g., determined) coherence (or level of coherence) of the sensor data with to the respective expected value. The signal reliability factor may range, for example, from 0 to 1, wherein 0 may indicate substantially no coherence (or no correlation) and 1 may indicate a substantially perfect match (e.g., a high level of coherence or correlation).

The Logical Coherence Module (LCM) may be configured to is provide the (e.g., position coded) signal reliability factor to the General Setting Matrix (e.g., the LCM may be configured to output coherence data (e.g., coherence value(s) into the GSM). Based on the LCM-data, a corresponding configuration for the sensor systems (e.g., corresponding sensor data) may be determined (e.g., retrieved from the GSM). By way of example, the Global Setting Matrix (GSM) may be configured (e.g., programmed) to determine, based on the signal reliability factor (e.g., on the probability), whether to keep the normal procedure or to change to another sensor system or sensor system combination or to output default emergency values. The default emergency values may be used for further vehicle guidance.

In various embodiments, the Logical Coherence Module (LCM) may be configured (e.g., programmed and/or trained) to evaluate (misleading) combined sensor signals (e.g., combined sensor data), for example in case of a multiple sensor attack. The Logical Coherence Module (LCM) may be configured to perform said evaluation by comparison of the sensor data with other data sets (e.g., vehicle-internal and/or vehicle-external data sets).

A Logical Coherence Module (LCM) may be configured to evaluate the occurrence of an attack in case sensor data suddenly indicate an opposite situation or scenario with respect to immediately previous sensor data. As an example, the Logical Coherence Module (LCM) may be configured to evaluate the occurrence of an attack in case a previously detected and registered object suddenly vanishes (false negative) or suddenly appears (false positive). In this case, the Logical Coherence Module (LCM) may be configured to evaluate and to take into consideration whether the object may be a rapidly moving object (e.g., a drone, such as a flying drone).

In various embodiments, the Logical Coherence Module (LCM) may include Deep Learning and/or Artificial Intelligence (AI) methods, e.g. based on neural networks. Illustratively, the Logical Coherence Module (LCM) may employ (or may at least be assisted by) Deep Learning and/or Artificial Intelligence (AI) methods for evaluating the coherence of the sensor data.

In various embodiments, information on the signal reliability factor (e.g., on the coherence of the sensor data) and/or on its determination (e.g., its assignment to the sensor data) may be provided to another device (e.g., to a vehicle-internal or vehicle-external device). As an example, the Logical Coherence Module (LCM) and/or the Global Setting Matrix (GSM) may be configured to provide the respective output signal to a (e.g., individual or combined) sensor control system. The sensor control system may be configured to initiate a change of sensor settings (e.g., camera focus, LIDAR beam intensity, Field-of-View angles, data compression, and the like). The data compression may include, for example, the use of a memory for intermediate data storage, as discussed in further detail below. As another example, the Logical Coherence Module (LCM) and/or the Global Setting Matrix (GSM) may be configured to generate a report and to send it to a traffic control station and/or to Traffic Authorities (e.g., indicating the location and the nature of the determined attack).

FIG. 2 shows a method 12400 in accordance with various embodiments. The method 12400 may include, in 12402, receiving sensor data. The (e.g., received) sensor data may be generated (e.g., provided) by one or more sensor systems. As an example, the one or more sensor systems may include one or more RADAR systems, and/or one or more camera systems, and/or one or more LIDAR systems (e.g., the LIDAR Sensing System 10), and/or one or more ultrasound systems. The one or more sensor systems may include one or more respective sensors (e.g., a LIDAR system may include a LIDAR sensor 52). The one or more sensor systems may be included in a vehicle (e.g., a vehicle with automated driving capabilities, e.g. an automated vehicle). The one or more sensor systems may be included in a sensor device. Illustratively, a sensor device may be a vehicle, or a sensor device may be included in a vehicle. The sensor data may be provided to a data processing system (e.g., of the vehicle or of a sensor device), for example the sensor data may be provided a Logical Coherence Module (LCM) of the data processing system.

The sensor data may describe, for example, an environment surrounding the one or more sensor systems (e.g., an environment surrounding the vehicle). As an example, the sensor data may describe driving related or traffic related information (e.g., the presence of other vehicles, the presence and the meaning of a traffic sign, the presence of an obstacle, and the like). As another example, the sensor data may describe an atmospheric condition (e.g., surrounding the vehicle).

The method 12400 may further include, in 12404, determining a signal reliability factor for the received sensor data (e.g., the Logical Coherence Module may be configured to determine the signal reliability factor).

The signal reliability factor may describe or represent a coherence (e.g., a correlation or an agreement) of the received sensor data with an expected value for the received sensor data (e.g., with expected or predicted sensor data, for example with a range of expected values for the received sensor data). The signal reliability factor may be a numerical value representing the coherence (or the level of coherence), for example ranging from 0 (non-coherent) to 1 (fully coherent). Illustratively, the signal reliability factor may provide an indication whether the received sensor data are reliable (e.g., credible) or not (e.g., whether the received sensor data make sense or not, for example in a specific vehicle condition). Further illustratively, the signal reliability factor may describe a deviation (in other words, a difference) of the received sensor data from the expected value for the received sensor data.

The expected value for the received sensor data may be determined based on previous sensor data. Stated differently, the coherence of the received sensor data may be determined based on previous sensor data (e.g., the signal reliability factor for the received sensor data may be determined based on previous sensor data). The previous sensor data may have been received (e.g., by the Logical Coherence Module) at an antecedent (in other words, previous) time point with respect to the (e.g., newly received) sensor data. A time difference between the previous sensor data and the newly received sensor data (e.g., a time difference between the reception of the previous sensor data and the reception of the sensor data) may be less than 5 minutes, for example less than 1 minute, for example less than 30 seconds. The previous sensor data may have been generated by the same sensor system or the same combination of sensor systems that provided the newly received sensor data. Additionally or alternatively, the previous sensor data may have been generated by another sensor system or another combination of sensor systems. A signal reliability factor for the previous sensor data may have been determined, which may indicate that the previous sensor data are reliable. As an example, in case a camera system or a LIDAR sensor system indicates the sudden appearance (or disappearance) of an object (e.g., absent (or present) according to the immediately previous sensor data), a low coherence with the previous sensor data may be determined (and the reliability of the measurement may be questioned).

The expected value for the received sensor data may be determined based on other sensor data (e.g., the method may include receiving other sensor data, for example the Logical Coherence Module may be configured to receive other sensor data). The received sensor data may be (e.g., first) sensor data generated by a first sensor system or a first combination of sensor systems. The expected value for the first sensor data may be determined based on (e.g., second) sensor data generated by a second sensor system or a second combination of sensor systems (e.g., the coherence of the first sensor data may be determined based on the second sensor data). Stated differently, the signal reliability factor for the received sensor data may be determined based on sensor data generated by another sensor system or another combination of sensor systems. Illustratively, the coherence of the received sensor data may be determined by means of a combination of sensor data from different sources. As an example, the reliability of sensor data generated by an ultrasound system may be determined (e.g., confirmed) by taking into account sensor data generated by a camera system, and vice versa (e.g., by checking the correspondence between the respective sensor data).

The expected value for the received sensor data may be determined based on a vehicle condition. Stated differently, the coherence of the received sensor data may be determined based on the vehicle condition (e.g., the signal reliability factor for the received sensor data may be determined based on the vehicle condition). A vehicle condition may describe a condition (e.g., a scenario) in which a vehicle is residing. The vehicle condition may include (e.g., describe or represent) position-coded information (e.g., information related to a location or coordinates of the vehicle). The vehicle condition (e.g., the position-coded information) may be determined, at least in part, on position data (e.g., GPS data). Illustratively, the method 12400 may include receiving position data (e.g., from a GNSS Module or a GPS Module). The method 12400 may include determining the vehicle condition (e.g., one or more factors defining the vehicle condition) based, at least in part, on the received position data (e.g., the Logical Coherence Module may be configured to determine the vehicle condition based on the received position data).

The vehicle condition may include (e.g., describe or represent) a location selective category (LSC) (or a plurality of location selective categories). The location selective category (LSC) may describe location-specific (e.g., position-specific) information, e.g. information related to a current location (e.g., current coordinates) of a vehicle. The location selective category (LSC) may describe a location of the vehicle and/or information related to the location (e.g., one or more position-coded rulings). As an example, the location selective category (LSC) may describe that the vehicle is located in a parking lot and may describe information related to the parking lot (e.g., speed limit, exits, direction of travel within the parking lot, etc.).

The vehicle condition may include an environmental setting (ES) (or a plurality of environmental settings). The environmental setting (ES) may describe one or more vehicle-external conditions, e.g. conditions that may affect a vehicle but that are not under direct control of the vehicle or of an occupant of the vehicle. The environmental setting (ES) may include, for example, weather, traffic density and the like, e.g. determined based on the current location of the vehicle. The vehicle condition may include a driving status (DS) (or a plurality of driving statuses). The driving status (DS) may describe one or more vehicle-internal conditions, e.g. conditions that may affect a vehicle and that may be controllable (or defined) by the vehicle or by an occupant of the vehicle. The driving status (DS) may include, for example, vehicle type and autonomy level of the vehicle, e.g. determined based on the current location of the vehicle (for example, for a vehicle traveling in a city the autonomy level may be different than for a vehicle traveling on a highway).

The vehicle condition may include one of the above-mentioned factors, or more than one of said factors, e.g. a combination of one or more of said factors.

The vehicle condition may be determined by means of sensor data (e.g., other sensor data with respect to the sensor data to be evaluated, for example by means of previous sensor data). The method 12400 may include determining the vehicle condition based, at least in part, on other sensor data (e.g., the Logical Coherence Module may be configured to perform such determination). Illustratively, the various factors may be determined based on (e.g., other) sensor data. As an example, a location specific category may be determined from or based on sensor data from a camera system. As another example, a traffic density may be determined based on RADAR and/or LIDAR measurements. As a further example, driver identification data may be known or may be determined from a camera system (e.g., imaging the inside of the vehicle).

A plurality of datasets (e.g., a database storing a plurality of datasets, e.g. a Global Setting Matrix) may be provided. The plurality of datasets may describe reference sensor data (a plurality of reference sensor data). The reference sensor data (e.g., each reference sensor data) may be associated with a respective vehicle condition. The reference sensor data may describe sensor data to be expected in the vehicle condition associated therewith. Illustratively, for each vehicle condition (e.g., each factor or combination of factors) respective expected sensor data may be stored (e.g., in the Global Setting Matrix). The method 12400 may include determining the expected value for the received sensor data from the reference sensor data (e.g., to determine a coherence of the received sensor data from the reference sensor data). Illustratively, the method 12400 may include retrieving reference sensor data associated with the current vehicle condition from a plurality of reference sensor data (e.g., from the Global Setting Matrix). By way of example, the Logical Coherence Module may be configured to perform such determination (and/or such retrieval).

It is intended that the various approaches to determine the coherence of the received sensor data described herein (e.g., the various approaches to determine the expected value of the received sensor data) may be used independently or may combined with one another (e.g., depending on a specific vehicle condition).

The method 12400 may include, in 12406, assigning the determined signal reliability factor to the received sensor data (e.g., associating the received sensor data with the determined signal reliability factor). Illustratively, the method 12400 may include generating information on the reliability of the received sensor data (and providing said information to a control system of the vehicle or of a sensor device, e.g. a sensor control system). By is way of example, the Logical Coherence Module may be configured to perform such association of the signal reliability factor with the received sensor data.

Based on the determined (and assigned) signal reliability factor, various actions may be performed and/or various decisions may be taken. The method 12400 may include controlling a vehicle taking into consideration (in other words, according to) the received sensor data and the signal reliability factor. Illustratively, one or more vehicle commands (e.g., vehicle steering) may be generated based on the received sensor data and the signal reliability factor.

As an example, in case the signal reliability factor is below a predefined threshold, the vehicle may be controlled ignoring the received sensor data (e.g., in case the signal reliability factor is particularly low, for example lower than 0.25 or lower than 0.1). As another example, the vehicle may be controlled in a way that ensures a safe operation of the vehicle in the assumption that the sensor data may be unreliable (e.g., an emergency command may be provided). The emergency command may be provided, for example, in case the signal reliability factor is between a lower threshold and an upper threshold (e.g., lower than 0.75 or lower than 0.5 and greater than 0.25 or greater than 0.1). The method 12400 may include controlling the vehicle based on the reference sensor data associated with the (e.g., current) vehicle condition. Illustratively, reference (e.g., expected) sensor data may be retrieved from the General Setting Matrix and may be used to control the vehicle. As another example, in case the signal reliability factor is above a predefined threshold (for example greater than 0.75 or greater than 0.9), the vehicle may be controlled according to the received sensor data. One or more vehicle commands may be generated that take into account the information provided by the sensor data (for example, the presence of an obstacle or a speed limit to be observed). Illustratively, the method 12400 may include disregarding the received sensor data or using the received sensor data to generate one or more vehicle commands depending on the assigned signal reliability factor. By way of example, a central control system of the vehicle may be configured to perform such control actions (e.g., after receiving the signal probability factor and the sensor data, for example from the Logical Coherence Module).

The method 12400 may include changing a configuration of one or more sensor systems based on the determined (and assigned) signal reliability factor. The configuration of one or more sensor systems that generated the received sensor data (e.g., individually or in combination) may be changed. Additionally or alternatively, the configuration of one or more other sensor systems (e.g., that did not generate the evaluated sensor data) may be changed. A sensor control system (e.g., a sensor setting system) may be configured to implement such configuration change. By way of example, the configuration may include one or more sensor systems to be deactivated (or deprioritized). Illustratively, in case the signal reliability factor is below a predetermined threshold, the one or more sensor systems that generated the received (e.g., unreliable) sensor data may be deactivated (e.g., at least temporarily). One or more other sensor systems may be used instead, e.g. may be activated or prioritized with respect to the one or more sensor systems that generated the received sensor data. Illustratively, the configuration may include a number (or a combination) of sensor systems to be deactivated (or deprioritized) and/or a number (or a combination) of sensor systems to be activated (or prioritized). As another example, in case the signal reliability factor is below the predefined threshold, the one or more sensor systems that generated the received sensor data may be controlled to repeat the measurement (e.g., the respective data acquisition rate may be increased), to perform further evaluation of the reliability of the sensor data. As a further example, in case the signal reliability factor is below the predefined threshold, data may be retrieved from a memory for intermediate data storage (e.g., redundant and/or less relevant data may be used for assessing the reliability of the sensor data). As a further example, one or more other sensor systems may be controlled to perform a measurement in the area (e.g., in the angular segment) that had been interrogated by the one or more sensor systems that generated the received sensor data.

The method 12400 may include selecting the configuration from a plurality of configurations. Each configuration may be associated with a respective vehicle condition. Illustratively, based on the (e.g., determined) vehicle condition, a corresponding (e.g., optimized) configuration for the one or more sensors may be selected (or an alternative configuration in case of low signal reliability factor). The configurations may be stored, for example, in the Global Setting Matrix.

The method 12400 may include storing the signal reliability factor. Additionally or alternatively, the method 12400 may include storing information describing the assignment of the reliability factor to the received sensor data (e.g., information on the vehicle condition, information on how the sensor data deviate from the expected sensor data, information on a possible cause for the deviation, and the like). The signal reliability factor and the related information may be stored, for example, in a memory of the vehicle or of the Logical Coherence Module (LCM). Additionally, or alternatively, the reliability factor and the related information may be stored in the Global Setting Matrix.

The method 12400 may include transmitting the signal reliability factor to another device (e.g., a vehicle-external device). Additionally, or alternatively, the method 12400 may include transmitting information describing the assignment of the reliability factor to the received sensor data to the other device. The other device may be, for example, a traffic control station or another vehicle (for example, to indicate a potential source of disturbance for the sensor systems). The other device may be Traffic Authorities (e.g., it may be a communication interface with the Traffic Authorities). Illustratively, the method 12400 may include determining based on the signal reliability factor whether the received sensor data have been corrupted due to an adversarial attack. The signal reliability factor may describe a probability of the received sensor data being affected by an adversarial attack (or by natural causes). As an example, in case the signal reliability factor is below a predetermined threshold, it may be determined that an adversarial attach has occurred. Corresponding information may be sent to the Traffic Authorities.

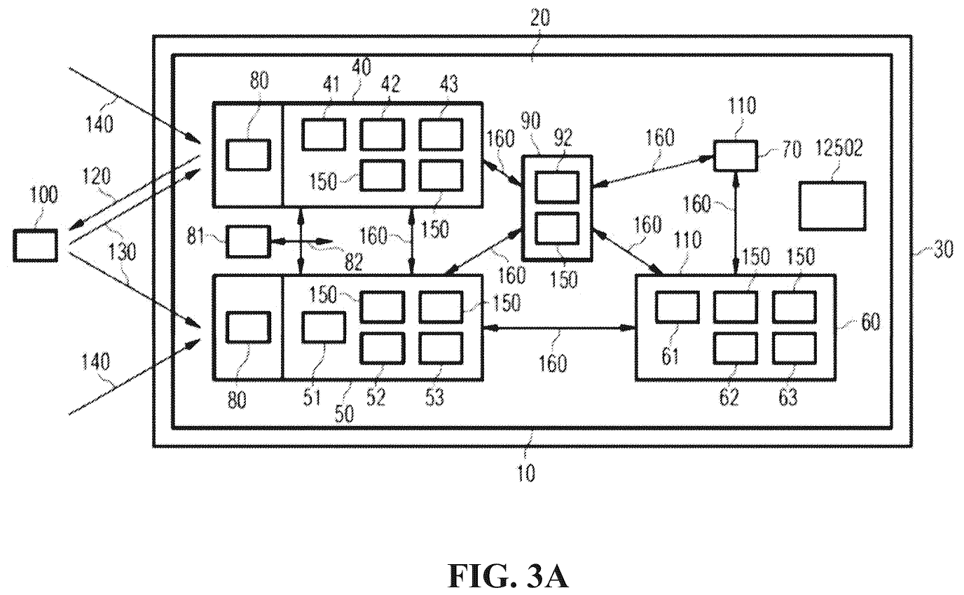

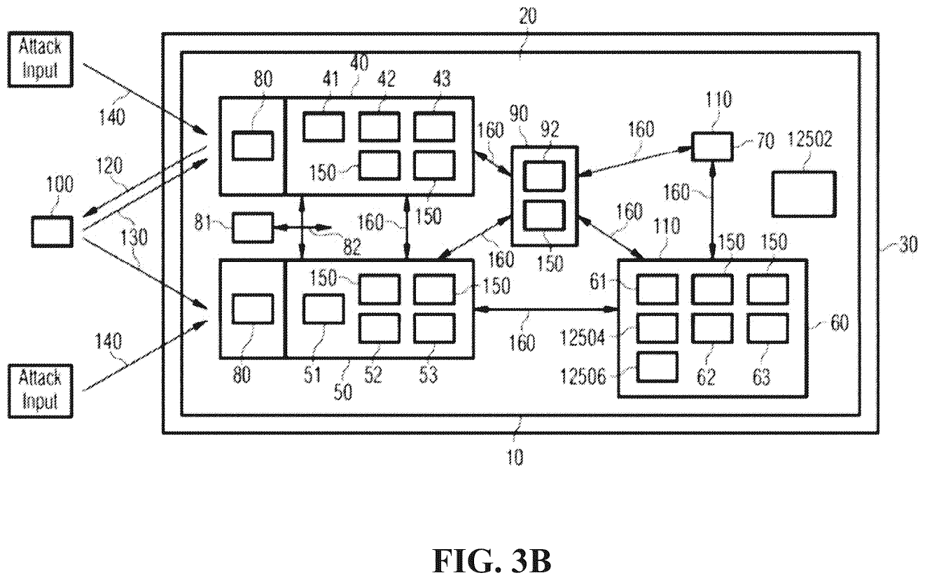

FIG. 3A and FIG. 3B show each a system in a schematic view in accordance with various embodiments.

The system may be configured to implement the method 12400 described in relation to FIG. 2. The system may be or may be configured as the LIDAR Sensing System 10 (e.g., the Retrofit LIDAR sensor system 10) described, for example, in relation to FIG. 1. It is intended that the system illustrated in FIG. 3A and FIG. 3B may include one or more of the components (e.g., all the components) of the LIDAR Sensing System 10 as described, for example, in relation to FIG. 1. The system may be integrated or embedded in a sensor device (e.g., in the LIDAR Sensor Device 30), for example a housing, a vehicle, a vehicle headlight.

The system may be configured to receive and measure electromagnetic or other types of object-reflected or object-emitted radiation 130, but also other wanted or unwanted electromagnetic radiation 140 (e.g., one or more attack inputs, e.g. one or more inputs manipulated to fool the system, as illustrated for example in FIG. 3B). The system may be configured to determine a position of the system (e.g., of the sensor device, e.g. of the vehicle). The system may include a position module 12502 (e.g., a GPS module, e.g. a GPS sensor). The position module 12502 may be configured to generate position data (or to receive position data, for example from an external device, such as a traffic control station).

The system may include a data processing system (e.g., the LIDAR data processing system 60). The data processing system may be configured to perform signal processing 61, data analysis and computing 62, sensor fusion and other sensing functions 63. The data processing system may be configured to check (e.g., to evaluate) the coherence of the sensor data (e.g., generated by a sensor of the system, e.g. the LIDAR sensor 52, or provided from a sensor signal generated by the sensor). The data processing system may include a logical coherence module 12504 (e.g., a coherence checking system), configured as described above. Illustratively, the logical coherence module 12504 may be configured to perform the method 12400 (or at least part of the method 12400). The data processing system may include the Global Setting Matrix 12506, configured as described above. The system may include a data management system (e.g., the LIDAR sensor management system 90) configured to manage input and output data (e.g., to communicate with system-external or vehicle-external devices). The data processing system (e.g., the logical coherence module 12504) may employ, at least in a supportive way, any other suitable and connected device including any cloud-based services.

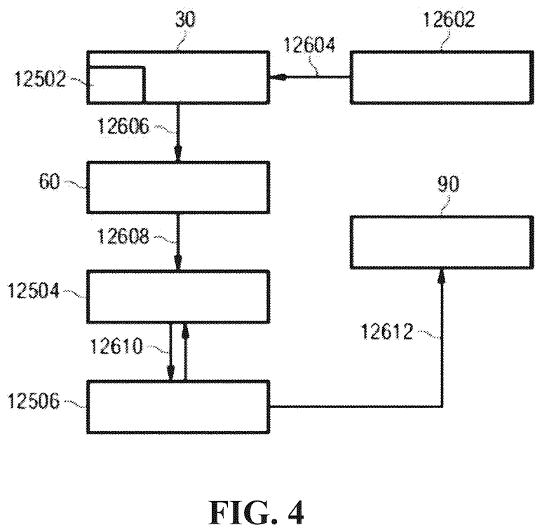

FIG. 4 shows a system and a signal path in a schematic view in accordance with various embodiments. Illustratively, FIG. 4 shows a flow chart related to the reception and processing of a signal input (e.g., of an adversarial signal).

An input provider 12602 may provide an input signal 12604 to the system (e.g., to the sensor device 30). The input provider 12602 may be, for example, an object (e.g., a vehicle or a traffic sign) in the field of view of the system. The input signal 12604 may be a genuine input signal or it may be an adversarial signal, e.g. a manipulated signal (e.g., the input provider 12602 may be a provider of adversarial signals, e.g. a manipulated traffic sign, or a vehicle emitting light or displaying a manipulated image).

The system (e.g., the sensor device 30) may be configured to provide sensor data 12606 generated according to the input signal 12604 to the data processing system (e.g., to the LIDAR data processing system 60). The data processing system may be configured to provide the sensor data 12608 (e.g., after an initial pre-processing) to the logical coherence module 12504. The logical coherence module 12504 may be configured to evaluate the coherence of the sensor data 12608 and to provide coherence data 12610 as an output. The coherence data 12610 may include or may describe the signal reliability factor assigned to the sensor data 12608, and/or information related to its assignment. The logical coherence module 12504 may be configured to provide the coherence data 12610 to the Global Setting Matrix 12506. Additionally or alternatively, the Global Setting Matrix 12506 may be configured to provide data to the logical coherence module 12504 (e.g., data for evaluating the reliability of the sensor data 12608, such as data describing the expected value for the sensor data 12608, for example location selective categories, environmental settings, and driving scenarios). Based on the received coherence data 12610, the Global Setting Matrix 12506 may be configured to provide an input 12612 (e.g., input data) to the data management system (e.g., the LIDAR sensor management system 90). Additionally or alternatively, the Global Setting Matrix 12506 may be configured to provide the input data to Traffic Authorities. The data management system may be configured to store the received input data and/or to transmit the received input data to a system-external device.

Various embodiments as described with reference to FIG. 2 to FIG. 4 may be combined with intelligent navigation systems.

In the following, various aspects of this disclosure will be illustrated:

Example 1u is a method. The method may include receiving sensor data. The method may include determining a signal reliability factor for the received sensor data. The signal reliability factor may describe a coherence of the received sensor data with an expected value for the received sensor data. The method may include assigning the determined signal reliability factor to the received sensor data.

In Example 2u, the subject-matter of example 1u can optionally include controlling a vehicle taking into consideration the received sensor data and the assigned signal reliability factor.

In Example 3u, the subject-matter of any one of examples 1u or 2u can optionally include that disregarding the received sensor data or using the received sensor data to generate one or more vehicle commands depending on the assigned signal reliability factor.

In Example 4u, the subject-matter of any one of examples 1u to 3u can optionally include that the signal reliability factor describes a deviation of the received sensor data from the expected value for the sensor data.

In Example 5u, the subject-matter of any one of examples 1u to 4u can optionally include that the expected value for the received sensor data is determined based on previous sensor data received at an antecedent time point with respect to the sensor data.

In Example 6u, the subject-matter of any one of examples 1u to 5u can optionally include that the received sensor data are first sensor data generated by a first sensor system. The method may further include receiving second sensor data generated by a second sensor system. The method may further include determining the expected value for the first sensor data based on the received second sensor data.

In Example 7u, the subject-matter of any one of examples 1u to 6u can optionally include that the expected value for the received sensor data is determined based on a vehicle condition.

In Example 8u, the subject-matter of example 7u can optionally include that the vehicle condition includes a location selective category, and/or an environmental setting, and/or a driving status.

In Example 9u, the subject-matter of any one of examples 7u or 8u, can optionally include receiving position data. The position data may describe a position of a vehicle. The method may further include determining the vehicle condition based at least in part on the received position data.

In Example 10u, the subject-matter of any one of examples 7u to 9u can optionally include determining the vehicle condition based on other sensor data.

In Example 11u, the subject-matter of any one of examples 7u to 10u can optionally include determining the expected value for the received sensor data from reference sensor data. The reference sensor data may be associated with a respective vehicle condition.

In Example 12u, the subject-matter of any one of examples 1u to 11u can optionally include changing a configuration of one or more sensor systems based on the determined signal reliability factor.

In Example 13u, the subject-matter of example 12u can optionally include selecting the configuration for the one or more sensor systems from a plurality of configurations each associated with a respective vehicle condition.

In Example 14u, the subject-matter of example 13u can optionally include that the configuration includes a number of sensor systems to be deactivated and/or deprioritized.

In Example 15u, the subject-matter of any one of examples 1u to 14u can optionally include storing the signal reliability factor and information describing its assignment to the received sensor data.

In Example 16u, the subject-matter of any one of examples 1u to 15u can optionally include transmitting the signal reliability factor and information describing its assignment to the received sensor data to another device.

In Example 17u, the subject-matter of any one of examples 1u to 16u can optionally include that the signal reliability factor describes a probability of the received sensor data being affected by an adversarial attack.

Example 18u is a device, including one or more processors configured to perform a method of any one of examples 1u to 17u.

Example 19u is a vehicle, including the device of example 18u.

Example 20u is a computer program including instructions which, when executed by one or more processors, implement a method of any one of examples 1u to 17u.

### CONCLUSION

While various embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings is/are used. Those skilled in the art will recognize, or be able to ascertain using no more than routine experimentation, many equivalents to the specific advantageous embodiments described herein. It is, therefore, to be understood that the foregoing embodiments are presented by way of example only and that, within the scope of the appended claims and equivalents thereto, embodiments may be practiced otherwise than as specifically described and claimed. Embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the scope of the present disclosure.

The above-described embodiments can be implemented in any of numerous ways. The embodiments may be combined in any order and any combination with other embodiments. For example, the embodiments may be implemented using hardware, software or a combination thereof. When implemented in software, the software code can be executed on any suitable processor or collection of processors, whether provided in a single computer or distributed among multiple computers.

Further, it should be appreciated that a computer may be embodied in any of a number of forms, such as a rack-mounted computer, a desktop computer, a laptop computer, or a tablet computer. Additionally, a computer may be embedded in a device (e.g. LIDAR Sensor Device) not generally regarded as a computer but with suitable processing capabilities, including a Personal Digital Assistant (PDA), a smart phone or any other suitable portable or fixed electronic device.

Also, a computer may have one or more input and output devices. These devices can be used, among other things, to present a user interface. Examples of output devices that can be used to provide a user interface include printers or display screens for visual presentation of output and speakers or other sound generating devices for audible presentation of output. Examples of input devices that can be used for a user interface include keyboards, and pointing devices, such as mice, touch pads, and digitizing tablets. As another example, a computer may receive input information through speech recognition or in other audible format.

Such computers may be interconnected by one or more networks in any suitable form, including a local area network or a wide area network, such as an enterprise network, and intelligent network (IN) or the Internet. Such networks may be based on any suitable technology and may operate according to any suitable protocol and may include wireless networks, wired networks or fiber optic networks.

The various methods or processes outlined herein may be coded as software that is executable on one or more processors that employ any one of a variety of operating systems or platforms. Additionally, such software may be written using any of a number of suitable programming languages and/or programming or scripting tools, and also may be compiled as executable machine language code or intermediate code that is executed on a framework or virtual machine.

In this respect, various disclosed concepts may be embodied as a computer readable storage medium (or multiple computer readable storage media) (e.g., a computer memory, one or more floppy discs, compact discs, optical discs, magnetic tapes, flash memories, circuit configurations in Field Programmable Gate Arrays or other semiconductor devices, or other non-transitory medium or tangible computer storage medium) encoded with one or more programs that, when executed on one or more computers or other processors, perform methods that implement the various embodiments of the disclosure discussed above. The computer readable medium or media can be transportable, such that the program or programs stored thereon can be loaded onto one or more different computers or other processors to implement various aspects of the present disclosure as discussed above.

The terms “program” or “software” are used herein in a generic sense to refer to any type of computer code or set of computer-executable instructions that can be employed to program a computer or other processor to implement various aspects of embodiments as discussed above. Additionally, it should be appreciated that according to one aspect, one or more computer programs that when executed perform methods of the present disclosure need not reside on a single computer or processor but may be distributed in a modular fashion amongst a number of different computers or processors to implement various aspects of the present disclosure.

Computer-executable instructions may be in many forms, such as program modules, executed by one or more computers or other devices. Generally, program modules include routines, programs, objects, components, data structures, etc. that perform particular tasks or implement particular abstract data types. Typically the functionality of the program modules may be combined or distributed as desired in various embodiments.

Also, data structures may be stored in computer-readable media in any suitable form. For simplicity of illustration, data structures may be shown to have fields that are related through location in the data structure.

Such relationships may likewise be achieved by assigning storage for the fields with locations in a computer-readable medium that convey relationship between the fields. However, any suitable mechanism may be used to establish a relationship between information in fields of a data structure, including through the use of pointers, tags or other mechanisms that establish relationship between data elements.

Also, various advantageous concepts may be embodied as one or more methods, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the claims, as well as in the disclosure above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the eighth edition as revised in July 2010 of the United States Patent Office Manual of Patent Examining Procedures, Section 2111.03

For the purpose of this disclosure and the claims that follow, the term “connect” has been used to describe how various elements interface or “couple”. Such described interfacing or coupling of elements may be either direct or indirect. Although the subject matter has been described in language specific to structural features and/or methodological acts, it is to be understood that the subject matter defined in the appended claims is not necessarily limited to the specific features or acts described. Rather, the specific features and acts are disclosed as preferred forms of implementing the claims.

In the context of this description, the terms “connected” and “coupled” are used to describe both a direct and an indirect connection and a direct or indirect coupling.

1. A non-transitory computer readable medium having instructions tangibly stored thereon, wherein when executed by a processing entity, the instructions cause the processing entity to carry out a method of evaluating influence of an action performed by an external entity, the method comprising:
receiving sensor data;
determining a signal reliability factor for the received sensor data, wherein the signal reliability factor represents a statistical quality indication between the received sensor data and an expected value or an expected range of values; and
associating the signal reliability factor with the received sensor data.

2. The computer readable medium of claim 1, the method further comprising:
determining if the signal reliability factor satisfies criteria; and
discarding the received sensor data or using the received sensor data to generate one or more commands which are configured to control a central control system, depending on whether the signal reliability factor satisfies the criteria.

3. The computer readable medium of claim 2, wherein the criteria are satisfied if the signal reliability factor is less than a predefined threshold or the signal reliability factor is between a lower threshold and an upper threshold.

4. The computer readable medium of claim 1, wherein the expected value or the expected range of values is based on immediately preceding sensor data, the immediately preceding sensor data being received at an antecedent time point with respect to a time point when the sensor data is received.

5. The computer readable medium of claim 4, wherein a sensor system that generates the immediately preceding sensor data is identical to a sensor system that generates the received sensor data.

6. The computer readable medium of claim 4, in response to the signal reliability factor indicating that the received sensor data is incoherent with the immediately preceding sensor data, the method further comprises evaluating influence of the action performed by the external entity based on the signal reliability factor.

7. The computer readable medium of claim 1, wherein the received sensor data is first sensor data generated by a first sensor system, and the method further comprises receiving second sensor data from a second sensor system; and statistically inferring the expected value or the expected range of values based on the second sensor data.

8. The computer readable medium of claim 1, wherein the processing entity is associated with a vehicle, and the method further comprises determining a vehicle condition associated with the vehicle; and statistically inferring the expected value or the expected range of values based on the vehicle condition.

9. The computer readable medium of claim 8, wherein the vehicle condition includes at least one of a location selective category, an environmental setting, and a driving status.

10. The computer readable medium of claim 8, the method further comprising determining a sensor fusion priority corresponding to the vehicle condition, wherein the sensor fusion priority defines a particular number and combination of sensor systems to be used.

11. The computer readable medium method of claim 1, wherein the sensor data is generated by one or more sensor systems, the method further comprising changing a configuration of the one or more sensor systems based on the signal reliability factor.

12. The computer readable medium method of claim 11, wherein changing the configuration of the one or more sensor systems comprises deactivating and/or deprioritizing at least one of the one or more sensor systems.

13. The computer readable medium method of claim 1, wherein the signal reliability factor indicates a probability of the received sensor data being influenced by the action performed by the external entity.

14. The computer readable medium method of claim 1, wherein determining the signal reliability factor comprises applying statistical rules to the received sensor data and the expected value or the expected range to generate the statistical quality indication, wherein the statistical rules include Bayesian rulings or position-coded rulings.

15. A system comprising:
a processor in communication with a memory, the processor configured to execute instructions in the memory to cause the system to:
receive sensor data;
determine a signal reliability factor for the received sensor data, wherein the signal reliability factor represents a statistical quality indication between the received sensor data and an expected value or an expected range of values; and
associating the signal reliability factor with the received sensor data.

16. The system of claim 15, wherein the processor is further configured to execute the instructions in the memory to cause the system to determine if the signal reliability factor satisfies criteria;
and to discard the received sensor data or to use the received sensor data to generate one or more commands which are configured to control a central control system, depending on whether the signal reliability factor satisfies the criteria.

17. The system of claim 15, wherein the expected value or the expected range of values is based on immediately preceding sensor data, the immediately preceding data being received at an antecedent time point with respect to a time point when the sensor data is received.

18. The system of claim 15, wherein the processor is further configured to execute the instructions in the memory to cause the system to, in response to the signal reliability factor indicating that the received sensor data is incoherent with the immediately preceding sensor data, evaluate influence of the action performed by the external entity based on the signal reliability factor.

19. The system of claim 15, wherein the received sensor data is first sensor data generated by a first sensor system, and the processor is further configured to execute the instructions in the memory to cause the system to receive second sensor data from a second sensor system; and statistically infer the expected value or the expected range of values based on the second sensor data.

20. The system of claim 15, wherein the system is associated with a vehicle, and the processor is further configured to execute the instructions in the memory to cause the system to determine a vehicle condition associated with the vehicle; and statistically infer the expected value or the expected range of values based on the vehicle condition.

21. The system of claim 15, wherein the processor is further configured to execute the instructions in the memory to cause the system to determine the signal reliability factor by applying statistical rules to the received sensor data and the expected value or the expected range of values to generate the statistical quality indication, wherein the statistical rules include Bayesian rulings or position-coded rulings.
